(19) United States
(12) Patent Application Publication
(10) Pub. No.: US 2026/0136848 A1
(43) Pub. Date: May 14, 2026

(54) DEPOSITION OF METAL-CONTAINING FILMS

(71) Applicant: Lam Research Corporation, Fremont, CA (US)

(72) Inventors: David Joseph Mandia, Lake Oswego, OR (US); Douglas Walter Agnew, Portland, OR (US); Joel David Smith, Tualatin, OR (US); Matthew Bertram Edward Griffiths, Campbell, CA (US); Nathaniel Elba Richey, Beaverton, OR (US); Alexander Ray Fox, Portland, OR (US); Kyle Jordan Blakeney, Milpitas, CA (US); Dennis M. Hausmann, Lake Oswego, OR (US); Jeong-Seok Na, San Jose, CA (US); Chiukin Steven Lai, Sunnyvale, CA (US); Sivananda Krishnan Kanakasabapathy, Pleasanton, CA (US)

(21) Appl. No.: 19/119,205

(22) PCT Filed: Oct. 10, 2023
(86) PCT No.: PCT/US2023/034858

§ 371 Date: Apr. 8, 2025

Related U.S. Application Data
(60) Provisional application No. 63/379,379, filed on Oct. 13, 2022.
(60) Provisional application No. 63/432,992, filed on Dec. 15, 2022.

(51) Int. Cl. H10P 14/40; C07F 11/00; C23C 16/04; C23C 16/16; C23C 16/455; H10P 14/43

(52) U.S. Cl. CPC H10P 14/418; C07F 11/005; C23C 16/045; C23C 16/16; C23C 16/45553; H10P 14/43

(57) ABSTRACT

Provided are methods for depositing a metal-containing film by in situ generation of an iodine-bond containing metal species with an iodine-containing reagent and a metal-containing precursor followed by reduction at a process temperature below 400″° C. In particular, the film can be a molybdenum-containing film. The methods may also include simultaneous introduction of the reagent and the precursor or an optional pretreatment with a passivation gas. Also provided are methods for depositing molybdenum-containing films on semiconductor using low valent molybdenum-containing precursors. The low valent molybdenum precursors of one or two molybdenum atoms may have at least one ligand which is an isocyanohaloalkyl, an allyl, an aryl, a tertiary organophosphino or an alkoxide group.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### FIELD

This disclosure pertains to methods of semiconductor device manufacturing. Specifically, embodiments of this disclosure pertain to precursors used for deposition of molybdenum-containing films in semiconductor processing.

### BACKGROUND

In integrated circuit (IC) fabrication, deposition and etching techniques are used for forming patterns of materials, such as for forming metal lines embedded in dielectric layers. Some patterning schemes require conformal deposition of materials, where the deposited layer should follow the contour of protrusions and/or recessed features on the surface of the substrate. Atomic layer deposition (ALD) is often a preferred method of forming conformal films on a substrate, because ALD relies on adsorption of one or more reactants (precursors) to the surface of the substrate, and on subsequent chemical transformation of the adsorbed layer to the desired material. Because ALD uses sequential reactions that occur on the surface of the substrate, that are separated in time, and that are typically limited by the amount of the adsorbed reactant, this method can provide thin conformal layers having excellent step coverage.

Atomic Layer Deposition (ALD) is a known method for the deposition of thin films. It is a self-limiting, sequential unique film growing technique based on surface reactions that can provide atomic layer control and deposit conformal thin films of materials furnished by precursors onto substrates of varying compositions. In ALD, the precursors are conventionally separated during the reaction. The first precursor is passed over the substrate producing a monolayer on the substrate. Any excess unreacted precursor is pumped out of the process chamber. A second precursor is then passed over the substrate and reacts with the first precursor, forming a monolayer of film on the substrate surface. This cycle is repeated to create a film of desired thickness, often at a process temperature greater than 450° C.

Deposition of metal-containing films at lower temperatures (below 400° C.) would be advantageous for certain applications. At such reduced temperatures, the likelihood of impurities is increased. Therefore, ALD processes which can be performed at lower temperatures and which can minimize impurities are desirable.

Chemical vapor deposition (CVD) is another deposition method widely used in semiconductor processing. In CVD, the reaction occurs in the volume of the process chamber and is not limited by the amount of reactants adsorbed to the substrate. As a result, CVD-deposited films are often less conformal than ALD-deposited films. CVD is typically used in applications where step coverage is less important.

ALD and CVD may employ plasma to promote the reactions of the deposition precursors resulting in the formation of the desired films. The methods that make use of the plasma are known as plasma enhanced ALD (PEALD) and plasma enhanced CVD (PECVD). The methods that do not employ plasma are referred to as thermal ALD and thermal CVD.

While ALD and CVD are most commonly used for deposition of silicon-containing films, such as silicon oxide, silicon nitride, and silicon carbide, these methods are also suitable for deposition of some metals, most notably tungsten and cobalt.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are methods for depositing a metal-containing film by in situ generation (generation within the process chamber) of an iodine-bond containing metal species with an iodine-containing reagent and a metal-containing precursor followed by reduction at a process temperature below 400° C. In some instances, the methods may also include simultaneous introduction of the iodine-containing reagent and the metal-containing precursor or an optional pretreatment with a passivation gas. In particular, the precursor can be a molybdenum-containing precursor such as a low valent molybdenum precursor and the film can be a molybdenum-containing film. The methods may advantageously produce metal-containing films with fewer halogen-based or other impurities. Also provided are low valent molybdenum precursors of one or two molybdenum atoms which have at least one ligand which is an isocyanohaloalkyl, an allyl, an aryl, a tertiary organophosphino or an alkoxide group. Additionally, methods for depositing molybdenum-containing films, such as metallic molybdenum, molybdenum nitride (MoNₓ), molybdenum carbide (MoCₓ), molybdenum boride (MoBₓ), molybdenum silicide (MoSiₓ), and combinations thereof such as molybdenum carbonitride (MoCₓN_{y}), molybdenum boride carbide (MoBₓC_{y}), are provided.

Accordingly, in a first aspect, the present disclosure encompasses a method of depositing a film on a semiconductor substrate. In some embodiments, the method includes providing a semiconductor substrate in a process chamber; forming an iodine bond-containing metal species in the process chamber; and exposing the iodine bond-containing metal species to a reducing agent, thereby forming a metal-containing film on the semiconductor substrate; wherein the reducing agent comprises a hydrogen-containing gas source.

In some embodiments, forming the iodine bond-containing metal species includes (i) introducing a metal-containing precursor in the process chamber containing the semiconductor substrate; and (ii) introducing an iodine-containing reagent to react with the metal-containing precursor.

In some embodiments, forming the iodine bond-containing metal species includes (i) introducing an iodine-containing reagent to the process chamber comprising the semiconductor substrate; and (ii) introducing a metal-containing precursor to react with the iodine-containing reagent.

In some embodiments, the metal-containing precursor is a vanadium-containing precursor, niobium-containing precursor, tantalum-containing precursor, chromium-containing precursor, cobalt-containing precursor, titanium-containing precursor, hafnium-containing precursor, tungsten-containing precursor, iron-containing precursor, ruthenium-containing precursor, nickel-containing precursor, zinc-containing precursor, zirconium-containing precursor, copper-containing precursor, molybdenum-containing precursor or combinations thereof.

In some embodiments, the metal-containing precursor is a molybdenum-containing precursor.

In some embodiments, the molybdenum precursor has a structure of Formula (I), Formula (II) or Formula (III): MoLₙ (I), Mo₂Lₙ (II), or LₙMo(L′)ₘMoLₙ (III), wherein each L is independently a monodentate ligand, ambidentate ligand, bidentate ligand or tridentate ligand, L′ is a linking moiety, n is 2, 3, 4, 5 or 6; and m is 1, 2 or 3.

In some embodiments, each L is independently a monodentate ligand.

In some embodiments, the monodentate ligand is hydrogen, halo, hydroxy, alkyl silyl, silylalkyl, alkenyl, alkynyl, allyl, alkoxy, alkenoxy, alkynoxy, thioalkoxy, aliphatic acyl, —CF₃, nitro, amino, imino, —N(C₁-C₃ alkyl)C(O)(C₁-C₃ alkyl), —C₁-C₃ alkylamino, alkenylamino, alkynylamino, di(C₁-C₃ alkyl)amino, —C(O)O—(C₁-C₃ alkyl), —C(O)NH—(C₁-C₃ alkyl), —CH═NOH, —P(C₁-C₃ alkyl)₃, —PO₃H₂, —OPO₃H₂, —C(O)N(C₁-C₃ alkyl)₂, haloalkyl, alkoxycarbonyl, alkoxyalkoxy, carboxaldehyde, carboxamide, cycloalkyl, cycloalkenyl, cycloalkynyl, aryl, aroyl, aryloxy, arylamino, biaryl, thioaryl, heterocyclyl, alkylheterocyclyl, heterocyclylalkyl, heterocycloyl, alkylaryl, alkylcarbonyl, CO, ═O, ═S, ═N, —NO, aralkenyl, aralkyl, sulfonyl, sulfonamido, sulfonimido, carbamate, aryloxyalkyl, carboxyl, carboxy, —C(O)NH(benzyl), amido, azido, isocyanato, thiocyanato, isothiocyanato, cyano, isocyanoalkyl, isocyanohaloalkyl, isocyanoaryl, isocyanohaloaryl or cyclyl.

In some embodiments, the molybdenum-containing precursor is a molybdenum halide or a molybdenum oxyhalide.

In some embodiments, the molybdenum oxyhalide is Mo_{q}OₙYₘ, wherein Y is a halogen; n is 1 or 2; q is 1, 2 or 4; and m is 1, 2 or 11.

In some embodiments, the molybdenum oxyhalide is MoOF₄, Mo₄O₁₁I, MoO₂I, MoOBr₄, MoO₂Br₂, MoO₂Cl₂, MoOCl₄, Mo₂Cl₁₀ or combinations thereof.

In some embodiments, the molybdenum halide is MoCl₅ or MoF₆.

In some embodiments, the molybdenum-containing precursor is Mo(CO)₆ or C₁₆H₂₀Mo.

In some embodiments, the molybdenum-containing precursor is a low valent molybdenum-containing precursor.

In some embodiments, the low valent molybdenum precursor has an oxidation state of zero, one, two or three.

In some embodiments, the iodine-containing reagent is hydrogen iodide, iodine, alkyl iodide, iodosilane, alkyl iodosilane, metal iodide or metal bromide.

In some embodiments, the alkyl iodide is CH₃I, C₂H₅I, C₃H₇I, C₄H₉I, CH₂I₂, C₂H₄I₂, C₃H₆I₂ or C₄H₈I₂.

In some embodiments, the iodosilane is SiH₃I, SiH₂I₂, SiHI₃, SiI₄ or Si₂I₆.

In some embodiments, the alkyl iodosilane is Si(CH₃)I₃, Si(CH₃)₂I₂, Si(CH₃)₃I, Si(CH₃)(H)I₂, Si(CH₃)₂(H)I or Si(CH₃)(H)₂I.

In some embodiments, the metal iodide is TiI₄ or AlI₃.

In some embodiments, the iodine-containing reagent is BI₃.

In some embodiments, the iodine bond-containing metal species is MoI₂, MoI₃ or a combination thereof.

In some embodiments, the reducing agent is a hydrogen-containing gas source.

In some embodiments, the hydrogen-containing gas source is hydrogen, deuterium, hydrogen and argon, hydrogen and helium, hydrogen and oxygen, hydrogen and nitrogen, ammonia, singly deuterated ammonia, doubly deuterated ammonia, triply deuterated ammonia, hydrazine, an alcohol, an aldehyde or combinations thereof.

In some embodiments, (i), (ii) and exposing the iodine bond-containing metal species to the reducing agent are performed sequentially.

In some embodiments, the method also includes purging the process chamber with an inert gas after at least one of (i) and (ii).

In some embodiments, forming the iodine bond-containing metal species and exposing the iodine bond-containing metal species to the reducing agent are performed simultaneously.

In some embodiments, (ii) and exposing the iodine bond-containing metal species to the reducing agent are performed simultaneously.

In some embodiments, the method also includes purging the process chamber with an inert gas after at least one of (i) and simultaneous formation of the iodine bond-containing metal species and exposure of the iodine bond-containing metal species to the reducing agent.

In some embodiments, the method also includes purging the process chamber with an inert gas after at least one of (i) and (ii).

In some embodiments, the method also includes (iii) pretreatment with an iodine-containing reagent, a passivation gas or both an iodine-containing reagent and a passivation gas before (i).

In some embodiments, the method also includes simultaneous pretreatment with a passivation gas during (i).

In some embodiments, the method also includes purging the process chamber with an inert gas after at least one of (i), (ii) and (iii).

In some embodiments, the method also includes repeating (i), (ii) and exposing the iodine bond-containing metal species to the reducing agent in cycles to form the metal-containing film.

In some embodiments, the method also includes repeating (i) and simultaneous formation of the iodine bond-containing metal species and exposure of the iodine bond-containing metal species to the reducing agent in cycles to form the metal-containing film.

In some embodiments, the method also includes repeating (i) and (ii) in cycles to form the metal-containing film.

In some embodiments, the method also includes repeating (i) and (ii) and repeating (i), (ii) and exposing the iodine bond-containing metal species to the reducing agent in cycles to form the metal-containing film.

In some embodiments, the method also includes repeating (i), (ii) and exposing the iodine bond-containing metal species to the reducing agent in cycles to form the metal-containing film.

In some embodiments, the method also includes repeating (i), (ii), (iii) and exposing the iodine bond-containing metal species to the reducing agent in cycles to form the metal-containing film.

In some embodiments, the metal-containing film is an elemental molybdenum film and the semiconductor substrate has a plurality of recessed features, wherein sidewalls of the recessed features include dielectric material.

In some embodiments, the metal-containing film is a molybdenum nitride film and the semiconductor substrate has a plurality of recessed features, wherein sidewalls of the recessed features include dielectric material.

In some embodiments, the temperature of the process chamber is maintained at less than about 400° C.

In some embodiments, the temperature of the process chamber is maintained at about 200° C. to about 300° C., and the process chamber has a pressure of less than about 500 Torr.

In some embodiments, at least one of forming the iodine bond-containing metal species and forming the metal-containing film is atomic layer deposition, no-purge atomic layer deposition, pulsed chemical vapor deposition or plasma-enhanced atomic layer deposition.

In a second aspect, the present disclosure encompasses an apparatus for depositing a metal-containing layer on a semiconductor substrate. In some embodiments, the apparatus includes a process chamber; a substrate support for a semiconductor substrate positioned within the process chamber; a plasma generator configured to generate a plasma within the process chamber; one or more gas inlets into the process chambers and associated flow-control hardware; and a controller having at least one processor and a memory, wherein the at least one processor and the memory are communicatively connected with one another, the at least one processor is at least operatively connected with the associated flow-control hardware, and the memory stores computer-executable instructions for controlling the at least one processor to cause: forming of an iodine-bond containing metal species in the process chamber; and exposing of the iodine bond-containing metal species to a reducing agent, thereby forming a metal-containing film on the semiconductor substrate.

In a third aspect, the present disclosure encompasses a method of forming a molybdenum-containing layer on a substrate. In some embodiments, the method includes providing a substrate in a processing chamber; introducing a low valent molybdenum precursor and at least one reactant into the processing chamber, where the low valent molybdenum precursor comprises an oxidation state of zero, one, two or three, and where the low valent molybdenum precursor has a structure of Formula (I), Formula (II) or Formula (III): MoLₙ (I), Mo₂Lₙ (II), or LₙMo(L′)ₘMoLₙ (III), where each L is independently a monodentate ligand, ambidentate ligand, bidentate ligand or tridentate ligand, L′ is a linking moiety, n is 2, 3, 4, 5 or 6; and m is 1, 2 or 3; and reacting the low valent molybdenum precursor and the at least one reactant to form a molybdenum-containing layer on the substrate.

In some embodiments, the monodentate ligand includes hydrogen, halo, hydroxy, alkyl silyl, silylalkyl, alkenyl, alkynyl, allyl, alkoxy, alkenoxy, alkynoxy, thioalkoxy, aliphatic acyl, —CF₃, nitro, amino, imino, —N(C₁-C₃ alkyl)C(O)(C₁-C₃ alkyl), —C₁-C₃ alkylamino, alkenylamino, alkynylamino, di(C₁-C₃ alkyl)amino, —C(O)O—(C₁-C₃ alkyl), —C(O)NH—(C₁-C₃ alkyl), —CH═NOH, —P(C₁-C₃ alkyl)₃, —PO₃H₂, —OPO₃H₂, —C(O)N(C₁-C₃ alkyl)₂, haloalkyl, alkoxycarbonyl, alkoxyalkoxy, carboxaldehyde, carboxamide, cycloalkyl, cycloalkenyl, cycloalkynyl, aryl, aroyl, aryloxy, arylamino, biaryl, thioaryl, heterocyclyl, alkylheterocyclyl, heterocyclylalkyl, heterocycloyl, alkylaryl, alkylcarbonyl, CO, ═O, ═S, EN, —NO, aralkenyl, aralkyl, sulfonyl, sulfonamido, sulfonimido, carbamate, aryloxyalkyl, carboxyl, carboxy, C(O)NH(benzyl), amido, azido, isocyanato, thiocyanato, isothiocyanato, cyano, isocyanoalkyl, isocyanohaloalkyl, isocyanoaryl, isocyanohaloaryl or cyclyl.

In some embodiments, the monodentate ligand includes at least one isocyanato, isocyanoalkyl, isocyanohaloalkyl, isocyanoaryl, isocyanohaloaryl, alkoxy or haloalkoxy.

In some embodiments, the monodentate ligand is isocyanohaloalkyl.

In some embodiments, the monodentate ligand is at least one allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl or pyrimidinyl.

In some embodiments, the bidentate ligand has a structure of Formula (IV): -(E)e-(IV), wherein each E is independently NR, C(R)ₙ, Si(R)ₙ, S, O or P(R)ₙ; where each R is independently hydrogen, aryl, amino or aliphatic; e is 1, 2, 3, 4 or 5; and n is 0, 1 or 2.

In some embodiments, the bidentate ligand is —O(C(R)ₙ)ₘO—, —O(C(R)ₙ)ₘNR—, —C(R)₂P(R)₂C(R)₂P(R)₂—C(R)₂—or —C(R)₂P(R)₂N(R)P(R)₂—C(R)₂—; where each R is independently H, aliphatic, haloalkyl, alkylsilyl, alkylamino, amino or alkoxy, or R groups may be linked to form a ring; n is 0, 1 or 2; and m is 1, 2 or 3.

In some embodiments, the low valent molybdenum precursor has a structure of formula MoL₄.

In some embodiments, the low valent molybdenum precursor has one or two bidentate ligands.

In some embodiments, the low valent molybdenum precursor has a structure of Formula (V):

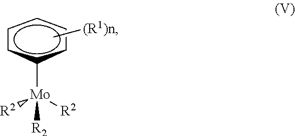

wherein each R¹ independently comprises alkyl or haloalkyl; each R² independently comprises carbonyl, cyano, isocyanoalkyl, isocyanohaloalkyl, isocyanoaryl, isocyanohaloaryl, isocyanato, or isothiocyanato; and n is 0, 1, 2 or 3.

In some embodiments, each R² independently is —CNR³, and where R³ comprises aliphatic, aryl or heterocyclyl.

In some embodiments, R³ is haloalkyl or haloaryl.

In some embodiments, R³ is pentafluoroethyl, heptafluoro-n-propyl, pentafluorobenzyl, —CF₃, —C₄F₉, —C₅F₁₁, —CH₂CF₃, —CH(CF₃)₂, —C(F)—CF₂, —C(F)═C(F)CF₃, —CF₂C(F)═CF₂, —CH(CH₃)(CF₃), —C(CH₃)₂(CF₃), —C(CF₃)₃ or nonafluoro-n-butyl.

In some embodiments, the low valent molybdenum precursor has a structure of Formula (VI):

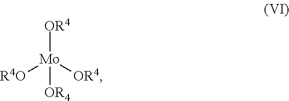

where each R⁴ is independently aliphatic, alkylsilyl, or haloalkyl; or R⁴ substituents may be linked to form a ring.

In some embodiments, each R⁴ is independently-CH₃, —C₂H₅, —C₃H₇, —C₄H₉, —C₅H₁₁, —CF₃, —C(F)═CF₂, —C(F)═C(F)CF₃, —CF₂C(F)—CF₂, —C₄F₉, —C₅F₁₁, —CH₂CF₃, —CH(CF₃)₂, -—CH(CH₃)(CF₃), —C(CH₃)₂(CF₃), —C(CF₃)₃, —Si(CH₃)₃, —Si(C₂H₅)₃, —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃ or —SO₂C₆H₄CH₃.

In some embodiments, the low valent molybdenum precursor has a structure of Formula (VII):

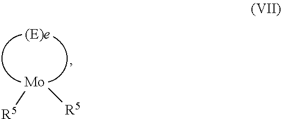

where each E independently comprises NR, C(R)ₙ, Si(R)ₙ, S, O or P(R)ₙ, where each R independently comprises hydrogen, aryl, amino or aliphatic; each R⁵ independently comprises halo, hydroxy, aliphatic, alkyl silyl, alkenyl, alkynyl, allyl, alkoxy, alkenoxy, alkynoxy, thioalkoxy, aliphatic acyl, —CF₃, nitro, amino, imino, —N(C₁-C₃ alkyl)C(O)(C₁-C₃ alkyl), —N(Si(CH₃)₃)₂, —C₁-C₃ alkylamino, alkenylamino, alkynylamino, di(C₁-C₃ alkyl)amino, —C(O)O—(C₁-C₃ alkyl), —C(O)NH—(C₁-C₃ alkyl), —CH═NOH, —P(C₁-C₃ alkyl)₃, —PO₃H₂, —OPO₃H₂, —C(O)N(C₁-C₃ alkyl)₂, haloalkyl, alkoxycarbonyl, alkoxyalkoxy, carboxaldehyde, carboxamide, cycloalkyl, cycloalkenyl, cycloalkynyl, aryl, aroyl, aryloxy, arylamino, biaryl, thioaryl, heterocyclyl, alkylheterocyclyl, heterocyclylalkyl, heterocycloyl, alkylaryl, alkylcarbonyl, ═O, ═S, —CO, aralkenyl, aralkyl, sulfonyl, sulfonamido, carbamate, aryloxyalkyl, carboxyl, carboxy, —C(O)NH(benzyl), amido, azido, isocyanato, isocyanoalkyl, isocyanohaloalkyl, isocyanoaryl, isocyanohaloaryl, thiocyanato, isothiocyanato, cyano or cyclyl; e is 1, 2, 3, 4 or 5; and n is 0, 1 or 2.

In some embodiments, the low valent molybdenum precursor has a structure of Formula (VIII):

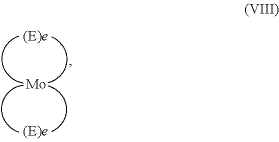

where each E independently comprises NR, C(R)ₙ, Si(R)ₙ, S, O or P(R)ₙ; where each R independently comprises hydrogen, aryl, amino or aliphatic; e is 1, 2, 3, 4 or 5; and n is 0, 1 or 2.

In some embodiments, the low valent molybdenum precursor has a structure of formula MoL₅.

In some embodiments, the low valent molybdenum precursor has one bidentate ligand or two bidentate ligands.

In some embodiments, the bidentate ligand has a structure of Formula (IV): -(E)ₑ—(IV), wherein each E is independently NR, C(R)ₙ, Si(R)ₙ, S, O or P(R)ₙ; where each R is independently hydrogen, aryl, amino or aliphatic; e is 1, 2, 3, 4 or 5; and n is 0, 1 or 2.

In some embodiments, the bidentate ligand is —O(C(R)ₙ)ₘO—, —O(C(R)ₙ)ₘNR—, —C(R)₂P(R)₂C(R)₂P(R)₂—C(R)₂—or —C(R)₂P(R)₂N(R)P(R)₂—C(R)₂—; where each R is independently H, aliphatic, haloalkyl, alkylsilyl, alkylamino, amino or alkoxy, or R groups may be linked to form a ring; n is 0, 1 or 2; and m is 1, 2 or 3.

In some embodiments, the low valent molybdenum precursor has two bidentate ligands.

In some embodiments, the low valent molybdenum precursor has a structure of Formula (X) or Formula (XI):

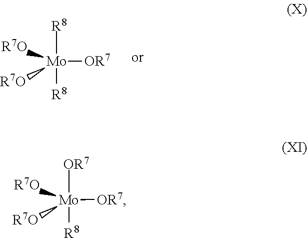

where each R⁷ is independently-CH₃, —C₂H₅, —C₃H₇, —C₄H₉, —C₅H₁₁, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃, —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, —P(O)(OCH₂CH₃)₂, CH(Si(CH₃)₃)(P(CH₃)₃), —SO₂CF₃, —SO₂C₃N₂H₃, —C(O)C₃F₇, —CHCHSO₂C₆H₅, —SO₂OCH₃ or —SO₂C₆H₄CH₃; and each R⁸ is independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR⁹, where R⁹ is aliphatic, aryl or heterocyclyl.

In some embodiments, R⁹ comprises haloalkyl or haloaryl.

In some embodiments, R⁹ is pentafluoroethyl, heptafluoro-n-propyl, pentafluorobenzyl, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃ or nonafluoro-n-butyl.

In some embodiments, the low valent molybdenum precursor has a structure of formula MoL₆.

In some embodiments, the low valent molybdenum precursor has one, two or three bidentate ligands.

In some embodiments, the bidentate ligand has a structure of Formula (IV): -(E)ₑ-(IV), where each E is independently NR, C(R)ₙ, Si(R)ₙ, S, O or P(R)ₙ; where each R is independently hydrogen, aryl, amino or aliphatic; e is 1, 2, 3, 4 or 5; and n is 0, 1 or 2.

In some embodiments, the bidentate ligand is —O(C(R)ₙ)ₘO—, —O(C(R)ₙ)ₘNR—, —C(R)₂P(R)₂C(R)₂P(R)₂—C(R)₂—or —C(R)₂P(R)₂N(R)P(R)₂—C(R)₂—; where each R is independently H, aliphatic, haloalkyl, alkylsilyl, alkylamino, amino or alkoxy, or R groups may be linked to form a ring; n is 0, 1 or 2; and m is 1, 2 or 3.

In some embodiments, the low valent molybdenum precursor has a structure of Formula (XII): Mo(X)ₚ (R¹⁰)_{q} (XII), where each X is independently chloro, fluoro, bromo or iodo; each R¹⁰ independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR¹¹, where R¹¹ is aliphatic, aryl or heterocyclyl; p is 1, 2, 3 or 4; q is 2, 3, 4 or 5; and p+q=6.

In some embodiments, R¹¹ is haloalkyl or haloaryl.

In some embodiments, R¹¹ is pentafluoroethyl, heptafluoro-n-propyl, pentafluorobenzyl, —CF₃, —C(F)═CF₂, —C(F)═C(F)CF₃, —CF₂C(F)—CF₂, —C₄F₉, —C₅F₁₁, —CH₂CF₃, —CH(CF₃)₂, —CH(CH₃)(CF₃), —C(CH₃)₂(CF₃), —C(CF₃)₃ or nonafluoro-n-butyl.

In some embodiments, the low valent molybdenum precursor has a structure of Formula (XIII): Mo(R¹²)ᵣ(R¹³)ₛ (XIII), where each R¹² is independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR¹⁴, where R¹⁴ is aliphatic, aryl or heterocyclyl; each R¹³ is independently trimethylphosphine, triethylphosphine, tri-i-propyl phosphine, triphenylphosphine, tris(trimethylsilyl)phosphine, tris(2-carboxyethyl) phosphine, tris(dimethylamino)phosphine, tris(o-tolyl)phosphine, tris(4-methoxyphenyl)phosphine or tris(2-furyl)phosphine; r is 1, 2, 3, 4, 5 or 6; s is 0, 1, 2, 3, 4 or 5; and r+s=6.

In some embodiments, R¹⁴ is haloalkyl or haloaryl.

In some embodiments, R¹⁴ is pentafluoroethyl, heptafluoro-n-propyl, pentafluorobenzyl, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃ or nonafluoro-n-butyl.

In some embodiments, the low valent molybdenum precursor has a structure of formula MoL₂.

In some embodiments, each L is independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, or pyrimidinyl.

In some embodiments, the low valent molybdenum precursor has a structure of formula MoL₃.

In some embodiments, the low valent molybdenum precursor has one bidentate ligand.

In some embodiments, the low valent molybdenum precursor is a structure of Formula (XIV):

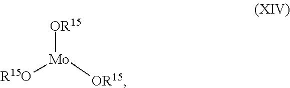

where each R¹⁵ is independently aliphatic, alkylsilyl or haloalkyl; or R¹⁵ substituents may be linked to form a ring.

In some embodiments, each R¹⁵ is independently-CH₃, —C₂H₅, —C₃H₇, —C₄H₉, —C₅H₁₁, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃, —CH₂Si(CH₃)₃, —CH₂P(CH₃)₃, —P(O)OH, —P(O)(OCH₃)₂, —CH(Si(CH₃)₃)₂, —C(Si(CH₃)₃)₃, —P(CH₃)₃, —P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃ or —SO₂C₆H₄CH₃.

In some embodiments, the low valent molybdenum precursor has a structure of Formula (XV): Mo₂(OR¹⁶)₆ (XV), where each R¹⁶ is independently aliphatic.

In some embodiments, the molybdenum-containing layer is molybdenum metal.

In some embodiments, the molybdenum-containing layer is molybdenum nitride, molybdenum carbide, molybdenum boride, molybdenum silicide or a combination thereof.

In some embodiments, the molybdenum-containing layer is a molybdenum-containing film.

In some embodiments, the at least one reactant is hydrogen, ammonia, diborane, water, hydrogen sulfide, a thiol, an alcohol, an amine, hydrazine, silane or disilane.

In a fourth aspect, the present disclosure encompasses a metal coordination complex. In some embodiments, the complex has a structure of Formula (V):

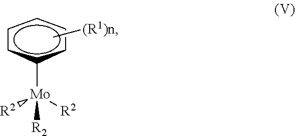

wherein each R¹ independently alkyl or haloalkyl; each R² is independently carbonyl, cyano, isocyanoalkyl, isocyanohaloalkyl, isocyanoaryl, isocyanohaloaryl, isocyanato or isothiocyanato; and n is 0, 1, 2 or 3.

In a fifth aspect, the present disclosure encompasses a metal coordination complex. In some embodiments, the complex has a structure of Formula (VI), Formula (IX), Formula (X), Formula (XI), or Formula (XV):

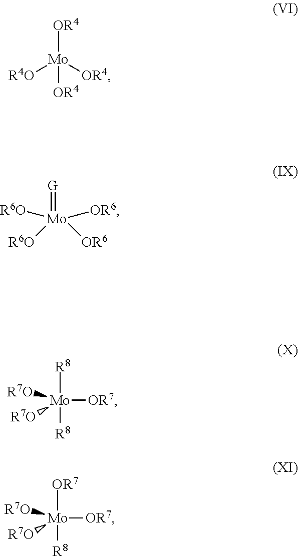

or Mo₂(OR¹⁶)₆ (XV), where R⁴, R⁶, R⁷ and R¹⁶ are each independently-CH₃, —C₂H₅, —C₃H₇, —C₄H₉, —C₅H₁₁, —CF₃, —C(F)—CF₂, —C(F)—C(F)CF₃, —CF₂C(F)—CF₂, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃, —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, —P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃ or —SO₂C₆H₄CH₃; G is ═O, ═NR, ═S or ═CR₂, where each R is independently an aliphatic, aryl, haloalkyl or haloaryl group; and each R⁸ is independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR⁹, where R⁹ is aliphatic, aryl or heterocyclyl.

In a sixth aspect, the present disclosure encompasses a metal coordination complex. In some embodiments, the complex has a structure of Formula (XII) or Formula (XIII): Mo(X)ₚ (R¹⁰)_{q} (XII) or Mo(R¹²)ᵣ (R¹³)ₛ (XIII), where each X is independently chloro, fluoro, bromo or iodo; where R¹⁰ and R¹² are each independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR¹⁴, where R¹⁴ is aliphatic, aryl or heterocyclyl; each R¹³ is independently trimethylphosphine, triethylphosphine, tri-i-propyl phosphine, triphenylphosphine, tris(trimethylsilyl)phosphine, tris(2-carboxyethyl) phosphine, tris(dimethylamino)phosphine, tris(o-tolyl)phosphine, tris(4-methoxyphenyl)phosphine or tris(2-furyl)phosphine; p is 1, 2, 3 or 4; q is 2, 3, 4 or 5; p+q=6; ris 1, 2, 3, 4, 5 or 6; s is 0, 1, 2, 3, 4 or 5; and r+s=6; with the proviso that at least one R¹⁰ of Formula (XII) is —CNR¹⁴; and with the proviso that at least one R¹² of Formula (XIII) is —CNR¹⁴.

In a seventh aspect, the present disclosure encompasses an apparatus for processing a substrate. In some embodiments, the apparatus includes a processing chamber, having a substrate holder and one or more inlets for introduction of reactants to the processing chamber; and an apparatus controller comprising program instructions for: causing introduction of a low valent molybdenum-containing precursor to the processing chamber; where the low valent molybdenum precursor comprises an oxidation state of zero, one, two or three, and where the low valent molybdenum precursor has a structure of Formula (I), Formula (II), or Formula (III): MoLₙ (I), Mo₂Lₙ (II), or LₙMo(L′)ₘMoLₙ (III), where each L is independently a monodentate ligand, ambidentate ligand, bidentate ligand or tridentate ligand, L′ is a linking moiety, n is 2, 3, 4, 5 or 6; and m is 1, 2 or 3; and causing the low valent molybdenum-containing precursor to react and form a molybdenum containing layer on the substrate.

In another aspect, a non-transitory computer machine-readable medium including program instructions for control of a deposition tool is provided, where the program instructions include code for causing any of the methods described herein.

The methods and apparatuses described herein can be integrated with the processes and apparatuses that perform photolithographic patterning. In one aspect, a system is provided, where the system includes any apparatus described herein and a stepper.

The molybdenum-containing precursors described herein can be used in ALD and CVD for deposition of molybdenum-containing films in a variety of applications. In some embodiments, the precursors are used to form conformal films. In other embodiments the precursors are used to fill recessed features with molybdenum-containing material (e.g., with molybdenum metal). For example, provided precursors and methods can be used for filling contact holes with high purity molybdenum metal.

In an eighth aspect, the present disclosure encompasses a method of depositing a film on a semiconductor substrate. In some embodiments, the method includes providing a semiconductor substrate in a process chamber; forming an iodine bond-containing metal species in the process chamber; and exposing the iodine bond-containing metal species to a reducing agent, thereby forming a metal-containing film on the semiconductor substrate; where forming the iodine bond-containing metal species includes (i) introducing a metal-containing precursor in the process chamber comprising the semiconductor substrate; and (ii) introducing an iodine-containing reagent to react with the metal-containing precursor or where forming the iodine bond-containing metal species includes (i) introducing an iodine-containing reagent to the process chamber including the semiconductor substrate; and (ii) introducing a metal-containing precursor to react with the iodine-containing reagent; where the metal-containing precursor is a low valent molybdenum precursor, the low valent molybdenum precursor has an oxidation state of zero, one, two or three, and where the low valent molybdenum precursor has a structure of Formula (I), Formula (II), or Formula (III): MoLₙ (I), Mo₂Lₙ (II), or LₙMo(L′)ₘMoLₙ (III), where each L is independently a monodentate ligand, ambidentate ligand, bidentate ligand or tridentate ligand, L′ is a linking moiety, n is 2, 3, 4, 5 or 6; and m is 1, 2 or 3.

These and other aspects of implementations of the subject matter described in this specification are set forth in the accompanying drawings and the description below.

### BRIEF DESCRIPTION OF THE DRAWINGS

FIGS. 1A-1C illustrate cross-sectional views of a substrate during deposition of metal-containing films in accordance with certain disclosed embodiments.

FIG. 2A is a process flow diagram for a method of forming metal-containing films by exposure to a metal-containing precursor, an iodine-containing reagent and a reducing agent in accordance with certain disclosed embodiments.

FIG. 2B provides examples of general structures for molybdenum precursors in accordance with certain disclosed embodiments.

FIG. 2C provides examples of low valent molybdenum precursors of the formula Mo(L) 6 in accordance with certain disclosed embodiments.

FIG. 2D provides examples of low valent dimolybdenum precursors in accordance with certain disclosed embodiments.

FIG. 3 is a process flow diagram for a method of forming metal-containing films by exposure to a metal-containing precursor and a simultaneous exposure to an iodine-containing reagent and a reducing agent in accordance with certain disclosed embodiments.

FIG. 4 is a process flow diagram for a method of forming metal-containing films by cyclic deposition process in accordance with certain disclosed embodiments.

FIG. 5 is a process flow diagram for a method of forming metal-containing films by a cyclic deposition process including pre-treatment with an iodine-containing reagent or a passivation gas in accordance with certain disclosed embodiments.

FIG. 6 is a process flow diagram for a method of forming metal-containing films by a cyclic deposition process including simultaneous pre-treatment with an iodine-containing reagent and a passivation gas in accordance with certain disclosed embodiments.

FIG. 7 is a process flow diagram for a method of forming molybdenum-containing films in accordance with certain disclosed embodiments.

FIG. 8 is a process flow diagram for a method of forming molybdenum metal films in accordance with certain disclosed embodiments.

FIG. 9 is a schematic presentation of an apparatus that is suitable for depositing molybdenum-containing films in accordance with certain disclosed embodiments.

FIG. 10 shows a schematic view of a multi-station processing system in accordance with certain disclosed embodiments.

FIG. 11 shows a schematic view of a multi-station processing system in accordance with certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Methods and precursors for depositing molybdenum-containing films on semiconductor substrates are provided. These methods and precursors can be used, for example, for depositing a blanket molybdenum-containing layer on a planar substrate, for depositing a conformal molybdenum-containing layer on a substrate having one or more recessed or protruding features, and for filling recessed features with molybdenum-containing materials. In some embodiments, methods and precursors are provided for selectively depositing molybdenum-containing layers over dielectric in a presence of exposed metal, or for selectively depositing molybdenum-containing layers over metal in a presence of exposed dielectric.

The methods can be used for deposition of a variety of molybdenum-containing materials including, but not limited to molybdenum metal, molybdenum nitride (MoNₓ), molybdenum carbide (MoCₓ), molybdenum boride (MoBₓ), molybdenum silicide (MoSiₓ), molybdenum boride carbide (MoBₓC_{y}), and molybdenum carbonitride (MoCₓN_{y}), where x and y indicate that the stoichiometry of these compounds may vary. Provided precursors are particularly suitable for deposition of molybdenum metal, such as high purity molybdenum metal with low levels of incorporation of other elements.

### Definitions

“Molybdenum metal” or “metallic molybdenum” as used herein, refers to material that consists essentially of molybdenum (Mo). Other elements (e.g., C, N, or O) can be present in molybdenum metal in small quantities (e.g., with a total content of less than about 15 atomic %, or less than about 10%, where hydrogen is not included in the calculation). “High purity molybdenum metal” as used herein refers to molybdenum metal that includes less than about 5% of other elements, such as less than about 1% of other elements, where hydrogen is not included in the calculation.

Molybdenum nitride (MoNₓ), molybdenum carbide (MoCₓ), molybdenum boride (MoBₓ), molybdenum silicide (MoSiₓ), molybdenum boride carbide (MoBₓC_{y}), and molybdenum carbonitride (MoCₓN_{y}), refer to materials that consist essentially of molybdenum and nitrogen (MoNₓ), molybdenum and carbon (MoCₓ), molybdenum and boron (MoBₓ), molybdenum and silicon (MoSiₓ), molybdenum, boron and carbon (MoBₓC_{y}), and molybdenum, carbon and nitrogen (MoCₓN_{y}), where x and y indicate that the stoichiometry of these compounds may vary. Other elements may be present in these compounds in small quantities, e.g., in an amount of less than about 10% atomic, where hydrogen is excluded from the calculation.

The term “semiconductor substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

By “aliphatic” is meant a hydrocarbon moiety having at least one carbon atom to 50 carbon atoms (C₁-50), such as one to 25 carbon atoms (C₁-25), or one to ten carbon atoms (C₁-10), and which includes saturated groups such as alkanes (or alkyl) and unsaturated groups such as alkenes (or alkenyl), alkynes (or alkynyl), and also includes cyclic versions thereof, and further including straight- and branched-chain arrangements, and all stereo and position isomers as well. Such a hydrocarbon can be unsubstituted or substituted with one or more groups, such as halogens or groups described herein for an alkyl group.

By “alkenyl” is meant an optionally substituted C₂₋₂₄ alkyl group having one or more double bonds. The alkenyl group can be cyclic (e.g., C₃-24 cycloalkenyl) or acyclic. The alkenyl group can also be substituted or unsubstituted. For example, the alkenyl group can be substituted with one or more substitution groups, as described herein for alkyl. Non-limiting unsubstituted alkenyl groups include C₂-8 alkenyl, C₂₋₆ alkenyl, C₂-5 alkenyl, C₂-4 alkenyl, or C₂-3 alkenyl. Exemplary, non-limiting alkenyl groups include vinyl or ethenyl (—CH═CH₂), 1-propenyl (—CH—CHCH₃), allyl or 2-propenyl (—CH₂—CH═CH₂), 1-butenyl (—CH═CHCH₂CH₃), 2-butenyl (—CH₂CH═CHCH₃), 3-butenyl (e.g.—CH₂CH₂CH—CH₂), 2-butenylidene (e.g., ═CH—CH═CHCH₃), and the like.

By “alkenylene” is meant a multivalent (e.g., bivalent) form of an alkenyl group, which is an optionally substituted C₂₋₂₄ alkyl group having one or more double bonds. The alkenylene group can be cyclic (e.g., C₃-24 cycloalkenyl) or acyclic. The alkenylene group can be substituted or unsubstituted. For example, the alkenylene group can be substituted with one or more substitution groups, as described herein for alkyl. Exemplary non-limiting alkenylene groups include —CH═CH—or —CH═CHCH₂—.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl.

Exemplary unsubstituted alkoxy groups include C₁-3, C₁-6, C₁-12, C₁-16, C₁-18, C₁-20, or C₁-24 alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr or nPr), isopropyl (i-Pr or iPr), cyclopropyl, n-butyl (n-Bu or nBu), isobutyl (i-Bu or iBu), s-butyl (s-Bu or sBu), t-butyl (t-Bu or tBu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃-24 cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1)C₁-6 alkoxy (e.g., —O-Ak, wherein Ak is optionally substituted C₁₋₆ alkyl); (2)amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9)C₃-8 cycloalkyl (e.g., a monovalent saturated or unsaturated non-aromatic cyclic C₃-8 hydrocarbon group); (10)halo (e.g., F, Cl, Br, or I); (11) heterocyclyl (e.g., a 3-, 4-, 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)-Het, wherein Het is heterocyclyl, as described herein); (14) hydroxyl (e.g., —OH); (15)N-protected amino; (16) nitro (e.g., —NO₂); (17)oxo (e.g., ═O); (18)-CO₂RA, where RA is selected from the group consisting of (a)C₁-6 alkyl, (b)C₄-18 aryl, and (c)(C₄-18 aryl) C₁₋₆ alkyl (e.g., -Lk-Ar, wherein Lk is a bivalent form of optionally substituted alkyl group and Ar is optionally substituted aryl); (19)—C(O)NR^{B}R^{C}, where each of RB and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20)—NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl)C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₂, C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched.

The alkylene group can also be substituted or unsubstituted. For example, the alkylene group can be substituted with one or more substitution groups, as described herein for alkyl.

By “alkylcarbonyl” is meant an alkyl group as previously defined appended to the parent molecular moiety through a carbonyl group. Exemplary, non-limiting alkylcarbonyl groups include methylcarbonyl, ethylcarbonyl, and isopropylcarbonyl among others.

The term “alkylsilyl”, as used herein, refers to SiR₃ group, wherein at least one R is an alkyl, and each R is independently selected from H and an alkyl. Alkylsilyls include mono, bis, and tris alkylsilyls. Examples of alkylsilyls include trimethylsilyl, dimethylsilyl, methylsilyl, triethylsilyl, diethylsilyl, and ethylsilyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl. Non-limiting unsubstituted alkynyl groups include C₂₋₈ alkynyl, C₂₋₆ alkynyl, C₂₋₅ alkynyl, C₂₋₄ alkynyl, or C₂₋₃ alkynyl. Exemplary, non-limiting alkynyl groups include ethynyl (—C≡CH), 1-propynyl (—C≡CCH₃), 2-propynyl or propargyl (—CH₂C≡CH), 1-butynyl (—C≡CCH₂CH₃), 2-butynyl (—CH₂C≡CCH₃), 3-butynyl (—CH₂CH₂C≡CH), and the like.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amido” is meant —N(R^{N1})C(O)—, where R^{N1} is H, optionally substituted alkyl, or optionally substituted aryl.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aminoalkyl” is meant an alkyl group, as defined herein, substituted by an amino group, as defined herein.

By “aminoaryl” is meant an aryl group, as defined herein, substituted by an amino group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “azido” is meant —N₃.

By “branched alkenyl” is meant an isomer of a straight chain alkenyl compound; one having alkyl groups bonded to the main carbon chain.

By “cyano” is meant —CN.

By “carbonyl” is meant a —C(O)-group, which can also be represented as >C═O.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “deposition” or “vapor deposition” is meant a process in which a metal layer is formed on one or more surfaces of a substrate from vaporized precursor composition(s) including one or more metal containing compounds. The metal-containing compounds are vaporized and directed to and/or contacted with one or more surfaces of a substrate (i.e., semiconductor substrate or semiconductor assembly) placed in a deposition chamber. Typically, the substrate is heated. These metal containing compounds form a non-volatile, thin, uniform metal-containing layer on the surface(s) of the substrate. One operation of the method is one cycle, and the process can be repeated for as many cycles necessary to obtain the desired metal thickness.

By “dicarbonyl” is meant any moiety or compound including two carbonyl groups, as defined herein. Non-limiting dicarbonyl moieties include 1,2-dicarbonyl (e.g., R^{C1}—C(O)—C(O) R^{C2}, in which each of R^{C1} and R^{C2} is, independently, optionally substituted alkyl, halo, optionally substituted alkoxy, hydroxyl, or a leaving group); 1,3-dicarbonyl (e.g., R^{C1}—C(O)—C(R^{1a}R^{2a})—C(O) R^{C2}, in which each of R^{C1} and R^{C2} is, independently, optionally substituted alkyl, halo, optionally substituted alkoxy, hydroxyl, or a leaving group and in which each of R^{1a} and R^{2a} is, independently, H or an optional substituent provided for alkyl, as defined herein); and 1,4-dicarbonyl (e.g., R^{C1}—C(O)—C(R^{1a}R^{2a})—C(R^{3a}R^{4a})—C(O) R^{C2}, in which each of R^{C1} and R^{C2} is, independently, optionally substituted alkyl, halo, optionally substituted alkoxy, hydroxyl, or a leaving group and in which each of R^{1a}, R^{2a}, R^{3a}, and R^{4a} is, independently, H or an optional substituent provided for alkyl, as defined herein).

The term “fluoroalkyl”, as used herein, refers alkyl groups containing one or more fluorine substituents. In some implementations fluoroalkyls contain exclusively fluorine substituents, such as in CF₃, C₂F₅, C₃F₇. Fluoroalkyls may be linear, branched and cyclic.

By “halo” is meant F, Cl, Br, or I.

By “halo containing substituent” is meant a group that contains a halo, such as a haloaliphatic or haloalkyl group.

By “haloaliphatic” is meant an aliphatic group, as defined herein, substituted with one or more halo.

By “haloalkenyl” is meant an alkenyl group, as defined herein, substituted with one or more halo.

By “haloalkynyl” is meant an alkynyl group, as defined herein, substituted with one or more halo.

By “haloalkyl” is meant an alkyl group, as defined herein, substituted with one or more halogen. Non-limiting unsubstituted haloalkyl groups include C₁₋₂ haloalkyl, C₁₋₃ haloalkyl, C₁₋₄ haloalkyl, C₁₋₅ haloalkyl, C₁₋₆ haloalkyl, C₂₋₃ haloalkyl, C₂₋₄ haloalkyl, C₂₋₅ haloalkyl, C₂₋₆ haloalkyl, or C₃₋₆ haloalkyl. Other non-limiting haloalkyl groups include —CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; —CH₂CXH_{3-y}, wherein y is 1, 2, or 3, and wherein each X is, independently, halo (F, Cl, Br, or I); —CX_{z1}H_{2-z1}CX_{z2}H_{2-z2}CX_{y}H_{3-y}, wherein each of z1 and z2 is, independently, 0, 1, or 2, wherein y is 0, 1, 2, or 3, and wherein each X is, independently, halo (F, Cl, Br, or I), in which at least one of z1, z2, or y is not 0; and —CX_{y}H_{1-z}[CX_{y1}H_{3-y1}][CX_{y2}H_{3-y2}], wherein z is 0 or 1, wherein each of y1 and y2 is, independently, 0, 1, 2, or 3, and wherein each X is, independently, halo (F, Cl, Br, or I), in which at least one of z, y1, or y2 is not 0.

By “haloalkylene” is meant an alkylene group, as defined herein, substituted with one or more halo.

By “heterocyclyl” is meant a 3-, 4-, 5-, 6- or 7-membered ring, unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benz isothiazolyl, benz isoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl, benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenz isoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for aryl.

By “hydroxyl” is meant —OH.

By “imino” is meant —NR—, in which R can be H or optionally substituted alkyl.

By “isocyanato” is meant —NCO.

By “isocyano” is meant —N═CO—, and includes nitriles of the formula RN═C—, wherein R is an aliphatic, aryl or heteroaryl group.

By “isothiocyanato” is meant —N═C—S.

By “low valent” is meant the lower oxidation states when a metal has multiple oxidation states.

By “oxo” is meant an ═O group.

By “oxy” is meant —O—.

By “silyl” is meant a —SiR¹R²R³ or —SiR¹R²-group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ (OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ (OR)_{b} (NR₂)_{c}, in which each Ris, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

Use of the above terms is meant to encompass substituted and unsubstituted moieties. Substitution may be by one or more groups such as alcohols, ethers, esters, amides, sulfones, sulfides, hydroxyl, nitro, cyano, carboxy, amines, heteroatoms, lower alkyl, lower alkoxy, lower alkoxycarbonyl, alkoxyalkoxy, acyloxy, halogens, trifluoromethoxy, trifluoromethyl, alkyl, aralkyl, alkenyl, alkynyl, aryl, cyano, carboxy, carboalkoxy, carboxyalkyl, cycloalkyl, cycloalkylalkyl, heterocyclyl, alkylheterocyclyl, heterocyclylalkyl, oxo, arylsulfonyl and aralkyaminocarbonyl, or any of the substituents of the preceding paragraphs or any of those substituents either directly attached or by suitable linkers. The linkers are typically short chains of 1-3 atoms containing any combination of —C—, —C(O)—, —NH—, —S—, —S(O)—, —O—, —C(O)—or —S(O)O—. Rings may be substituted multiple times.

The term “lower” modifying “alkyl”, “alkenyl”, “alkynyl”, “alkoxy” or “alkoxycarbonyl” refers to a C₁-C₆ unit for a particular functionality. For example, “lower alkyl” means C₁-C₆ alkyl.

By “substituted” is meant having one or more substituent moieties whose presence does not interfere with the desired function or reactivity. Examples of substituents alkyl, alkenyl, alkynyl, cycloalkyl (non-aromatic ring), Si(alkyl)₃, Si(alkoxy)₃, alkoxy, amino, alkylamino, alkenylamino, amide, amidine, guanidine, hydroxyl, thioether, alkylcarbonyl, alkylcaronyloxy, alkoxycarbonyloxy, carbonate, alkoxycarbonyl, aminocarbonyl, alkylthiocarbonyl, phosphate, phosphate ester, phosphonato, cyano, halo, acylamino, imino, sulfhydryl, alkylthio, thiocarboxylate, dithiocarboxylate, sulfate, sulfato, sulfonate, sulfamoyl, sulfonamide, nitro, nitrile, azido, heterocyclyl, ether, ester, silicon-containing moieties, thioester or a combination thereof. The substituents may themselves be substituted. For instance, an amino substituent may itself be mono or independently disubstituted by further substituents defined above, such as alkyl, alkenyl, alkynyl, and cycloalkyl (non-aromatic ring).

By “thiocyanato” is meant —SCN.

By “thioether” is meant to include to include both unidentate and multidentate (e.g. bidentate ot tridentate) thioethers, as well as ligands that contain both thioether and thiolate (or other) moieties.

By “unsubstituted” is meant any open valence of an atom being occupied by hydrogen. Also, if an occupant of an open valence position on an atom is not specified, then it is hydrogen.

As used herein, the term “about” is understood to account for minor increases and/or decreases beyond a recited value, which changes do not significantly impact the desired function of the parameter beyond the recited value(s). In some cases, “about” encompasses+/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

The implementations disclosed below describe deposition of a material on a substrate such as a wafer, substrate, or other work piece. The work piece may be of various shapes, sizes, and materials. In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates and can be scaled as appropriate for substrates or chambers of other sizes. In addition to semiconductor wafers, other work pieces that may be used implementations disclosed herein include various articles such as printed circuit boards and the like. The processes and apparatuses can be used in the fabrication of semiconductor devices, displays, LEDs, photovoltaic panels and the like.

By “unsaturated” is meant a moiety that contains double or triple carbon-carbon bonds.

By “unsaturated substituent” is meant a double or triple bond containing aliphatic chain, cyclic, aryl or heteroaryl group.

The term “independently selected”, when referring to R substituent selection in a molecule containing multiple R groups, means that the selection of R substituents at different atoms of a molecule is independent and that the selection of R substituents at one atom having multiple R substituents is also independent.

### Introduction & Context

ALD is a technique that deposits thin layers of material using sequential self-limiting reactions. ALD processes use surface-mediated deposition reactions to deposit films on a layer by-layer basis in cycles. As an example, an ALD cycle may include the following operations: (i) delivery/adsorption of a precursor, (ii) purging of precursor from the chamber, (iii) delivery of a second reactant and optionally ignite plasma, and (iv) purging of byproducts from the chamber. The reaction between the second reactant and the adsorbed precursor to form a film on the surface of a substrate affects the film composition and properties, such as non-uniformity, stress, wet etch rate, dry etch rate, electrical properties (e.g., breakdown voltage and leakage current), etc.

Unlike a chemical vapor deposition (CVD) technique, ALD processes use surface mediated deposition reactions to deposit films on a layer-by-layer basis. In one example of an ALD process, a substrate surface that includes a population of surface-active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas, is introduced to the chamber so that some of these molecules react with the first precursor adsorbed on the surface. In some processes, the second precursor reacts immediately with the adsorbed first precursor. In other embodiments, the second reactant reacts only after a source of activation is applied temporally. The chamber may then be evacuated again to remove unbound second reactant molecules. As described above, in some embodiments the chamber may not be completely evacuated. Additional ALD cycles may be used to build film thickness.

In some implementations, the ALD methods include plasma activation. As described herein, the ALD methods and apparatuses described herein may be conformal film deposition (CFD) methods.

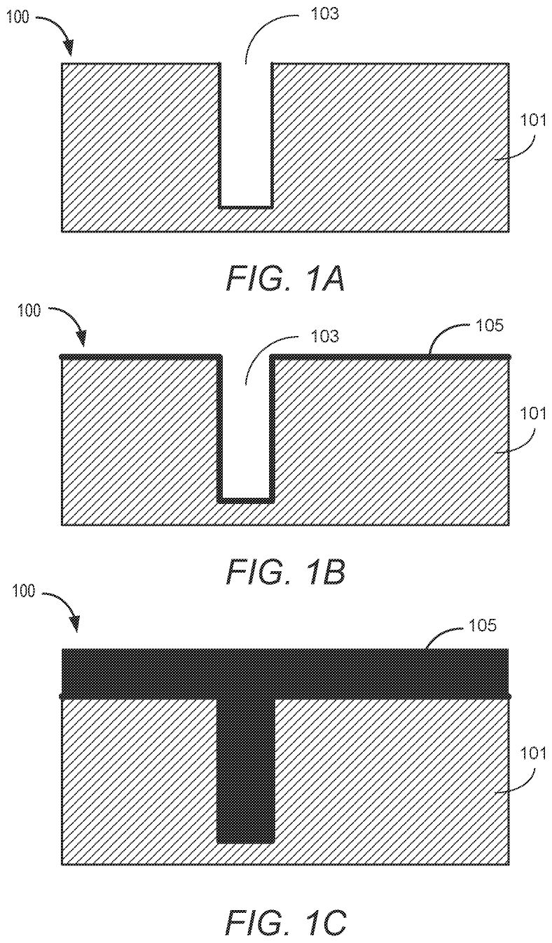

An illustration of a cross-sectional view 100 of a substrate during the deposition process is provided in FIG. 1A. The figure shows the substrate 101 having a recessed feature 103. A recessed feature may have sidewalls and a bottom. In general, the substrate 101 may include a variety of materials including dielectrics, metals and metal nitrides. A conformal layer of metal-containing film 105 is deposited on the substrate 101 using the methods and precursors described below. The resulting structure is shown in FIG. 1B. In some applications the process continues, and the recessed feature 103 is filled with the metal-containing material 105, as shown in FIG. 1C. The metal-containing film is deposited into the recessed feature, in some embodiments, using multiple depositions of conformal film as shown in FIGS. 1A-1C using a sequence of ALD or pulsed chemical vapor deposition cycles. In other embodiments the recessed feature may be filled using bottom-up film growth.

### Methods with Metal-Containing Precursor Introduction as First Step

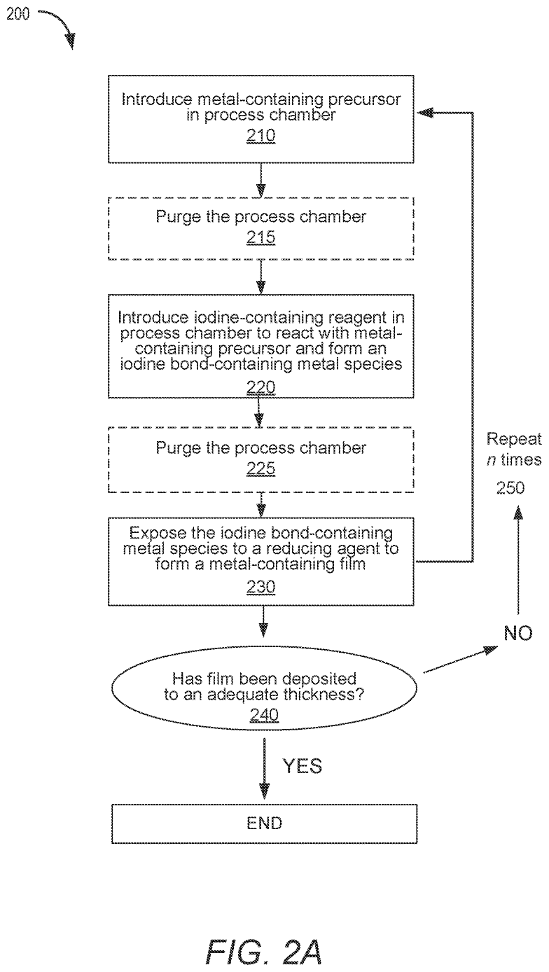

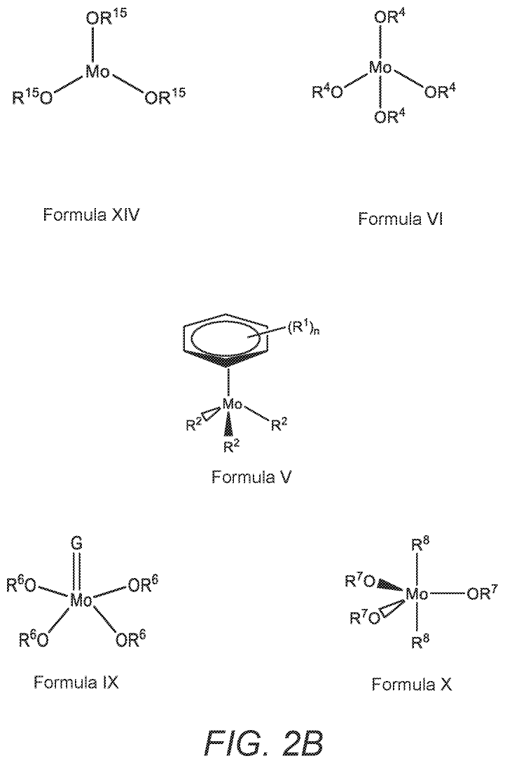

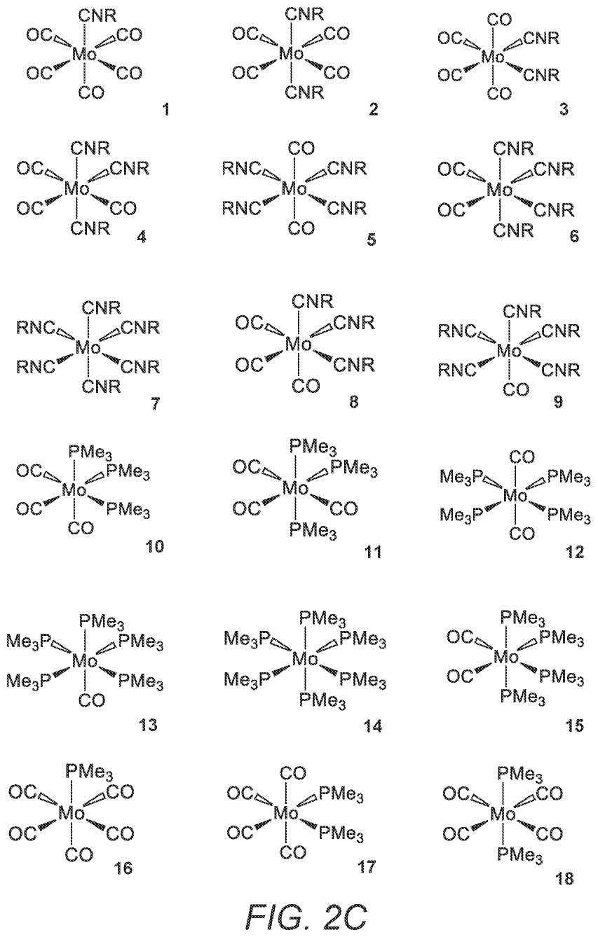

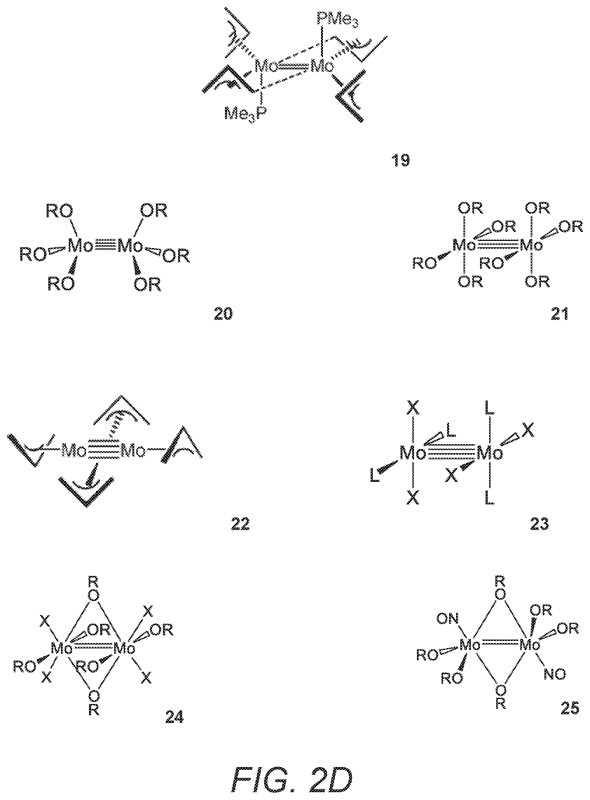

FIG. 2A is a flow chart illustrating a sequential and optionally cyclic method 200 for deposition of metal-containing films which begins with operation 210, introduction of a metal-containing precursor to a process chamber. In some embodiments, the metal-containing precursor is a molybdenum-containing precursor, and the deposited metal-containing film is a molybdenum-containing film. The metal-containing precursor may be flowed to a chamber housing the substrate at a flow rate between about 100 sccm and about 5000 sccm (e.g., about 100 to 2000 sccm). The precursor can be flowed for any useful period (e.g., about 0.1 to 10 seconds) and any useful pressure (e.g., about 1 to 500 Torr). The temperature of the process chamber may be maintained at a temperature of 100° C. to 500° C. in some embodiments, or about 400° C. or less in other embodiments. In certain embodiments, the temperature may be ultra-low, from about 200° C. to 300° C.

During operation 210, a push gas may be flowed. The push gas may be any inert gas, such as nitrogen (N₂), argon (Ar), or any other listed herein. The push gas may be provided to assist with pressure and/or temperature control of the process chamber, evaporation of a liquid reactant, more rapid delivery of the reactant, and/or as a sweep gas for removing process gases from the process chamber and/or process chamber plumbing. In some embodiments, the push gas is flowed to a chamber housing the substrate at a flow rate between about 100 sccm and about 5000 sccm (e.g., about 500 to 2000 sccm). Flow of the push gas with the metal-containing precursor can allow for dilution of the precursor, as well as pressure stability during operation.

In some embodiments, the metal-containing precursor may be a vanadium-containing precursor, niobium-containing precursor, tantalum-containing precursor, chromium-containing precursor, cobalt-containing precursor, titanium-containing precursor, hafnium-containing precursor, tungsten-containing precursor, iron-containing precursor, ruthenium-containing precursor, nickel-containing precursor, zinc-containing precursor, zirconium-containing precursor, copper-containing precursor, molybdenum-containing precursor or a combination thereof. The metal-containing precursors are discussed in the following paragraphs, beginning with molybdenum-containing precursors.

Molybdenum metal films have not been widely used in semiconductor processing, at least in part because molybdenum has a high affinity towards carbon, nitrogen, and oxygen, making it difficult to obtain molybdenum metal having low levels of incorporation of impurities, and, consequently, low resistivity. Many common molybdenum deposition precursors display low thermal stability, which results in insufficient step coverage in high aspect ratio features. Existing organometallic molybdenum precursors with molybdenum-carbon bonds can provide high levels of incorporation of carbon into the deposited molybdenum leading to high resistivity. For example, the use of molybdenum carbonyl compounds, such as Mo(CO)₆ can lead to incorporation of large amounts of carbon (e.g., at least 5 atomic %) into the growing molybdenum metal film, because molybdenum serves as a catalyst for CO dissociation. While molybdenum halides do not have this problem, the existing halide-based molybdenum-containing deposition precursors have a number of other undesirable properties. For example, the use of molybdenum hexafluoride (MoF₆) requires fluorine barrier and an etch stop layer, when molybdenum is deposited on a substrate containing exposed fluorine-susceptible layers (e.g., silicon-containing materials, such as silicon oxide-based dielectrics). Molybdenum pentachloride (MoCl₅) is another conventional precursor that has a number of drawbacks: it has a high melting point and may induce etching of the growing molybdenum film. Modifying the homoleptic halide precursors by exchanging halide ligands for oxo ligands, as in molybdenum oxychlorides MoOCl₄ and MoO₂Cl₂, increases volatility, but these precursors are difficult to reduce to the pure molybdenum metal due to strong molybdenum-oxygen double bonds. In addition, MoCl₅, MoOCl₄, and MoO₂Cl₂ are all high melting point corrosive solids, which are undesirable in high volume manufacturing.

Molybdenum precursors and deposition methods provided herein, can overcome one or more of these shortcomings. In some embodiments, high purity molybdenum metal films are deposited using provided precursors and methods, where the deposited high purity molybdenum metal film consists essentially of molybdenum and has less than about 5% atomic of other elements, such as less than about 3% atomic of other elements, or less than about 1% atomic of other elements (excluding hydrogen from the calculation). In some embodiments molybdenum metal films with resistivities of less than about 50 μΩ cm, such as less than about 30 μΩ cm for 100 Å thick films are provided. In some embodiments, particularly when fluorine-free precursors are used, the molybdenum metal can be deposited directly onto a substrate containing exposed fluorine-sensitive materials, without the need for protecting them with an etch stop layer. For example, molybdenum metal or other molybdenum-containing films can be deposited onto a substrate containing exposed silicon oxide-based dielectric, silicon-containing dielectrics, such as silicon nitride and silicon carbide, or amorphous or crystalline silicon or silicon germanium. Silicon oxide-based dielectrics, as used herein, refer to dielectrics containing silicon-oxygen bonds, and include thermally grown silicon oxide, silicates, silane (and related)-deposited oxide, TEOS (tetraethylorthosilicate)-deposited oxide and the like.

The precursors provided herein are amenable to vaporization and are stable at target temperatures and pressures. For example, in some embodiments the precursors are used in deposition reactions at temperatures of less than about 450° C., such as less than about 400° C.

In order to maintain appropriate volatility, in many embodiments discussed herein, the precursors having molecular weights of less than about 450 g/mol, such as less than about 400 g/mol.

The low valent molybdenum compounds described herein can advantageously provide high purity molybdenum metal in CVD and ALD deposition. Further, the use of these compounds can be associated with reduced etching of the substrate materials. These advantages are described for illustration purposes and do not limit the use of these compounds solely to molybdenum metal deposition or to deposition on etching-sensitive substrates.

Generally, molybdenum precursors may have from two (MoL₂) to six (MoL₆) ligands and can include molybdenum in a wide range of oxidation states ranging from 0 to +6.

Molybdenum precursors may also be dimolybdenum compounds having 1) two molybdenum atoms singly or multiply bonded to one another; or 2) two molybdenum atoms connected by a linking group such as a bidentate ligand.

Suitable molybdenum containing precursors include molybdenum halides and oxyhalides, such as fluorides, chlorides, bromides, oxyfluorides, oxychlorides, and oxybromides where molybdenum may be in any of the oxidation states from +2 to +6.

Molybdenum chloride precursors are given by the formula MoClx, where x is 2, 3, 4, 5, or 6, and include molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments, MoCl₅ or MoClo are used. While the description chiefly refers to MoClx precursors, in other embodiments, other molybdenum halide precursors may be used. Molybdenum halide precursors are given by the formula MoX_{z}, where X is a halogen (fluorine (F), chlorine (C₁), bromine (Br), or iodine (I)) and z is 2, 3, 4, 5, or 6. Examples of MoX_{z} precursors include molybdenum fluoride (MoF₆). In some embodiments, a non-fluorine-containing MoX_{y} precursor is used to prevent fluorine etch or incorporation. In some embodiments, a non-bromine-containing and/or a non-iodine-containing MoX_{y} precursor is used to prevent etch or bromine or iodine incorporation.

Molybdenum oxyhalide precursors are given by the formula MoO_{y}X_{z}, where X is a halogen (fluorine (F), chlorine (Cl), bromine (Br), or iodine (I)) and y and z are numbers greater than 0 such that MoO_{y}X_{z} forms a stable compound. Examples of molybdenum oxyhalides include molybdenum dichloride dioxide (MoO₂Cl₂), molybdenum tetrachloride oxide (MoOCl₄), molybdenum tetrafluoride oxide (MoOF₄), molybdenum dibromide dioxide (MoO₂Br₂), and the molybdenum iodides MoO₂I, and Mo₄O₁₁I.

In some embodiments discussed herein, the precursors having molecular weights of less than about 450 g/mol, such as less than about 400 g/mol.

In some embodiments the molybdenum-containing precursor has a formula MoXₙYₘ, wherein X is a chalcogen (e.g., oxygen or sulfur), Y is a halogen (e.g., fluorine, chlorine, bromine, or iodine), n is 0, 1, or 2 and m is 2, 3, 4, 5, or 6. Examples of halogen-containing molybdenum-containing precursors include without limitation MoCl₅, Mo₂Cl₁₀, MoO₂Cl₂, and MoOCl₄. Another example of a halogen-containing molybdenum-containing precursor is MoF₆.

### Low-Valent Molybdenum Complexes

Low valent molybdenum complexes or compounds are those having molybdenum in low oxidation states 0, +1, +2 or +3. In certain embodiments, the low valent molybdenum complexes may be efficacious precursors as it is easier to reduce Mo(I) to Mo(0) or Mo(II)/(III) to Mo(0) than it is to reduce the more commonly utilized Mo(IV)/(V) halide precursors.

Low valent molybdenum precursors may offer a less circuitous surface redox process to obtain fully reduced molybdenum metal films with minimal impurities. Without wishing to be bound by a particular theory, this is likely the result of the ease of reduction of low valent molybdenum precursors.

### Molybdenum Zero Complexes

Mo(0) precursors are advantageous because do not require any reduction steps, and are energetically facile, as their use provides a lower energy barrier to Mo film formation upon exposure to a reducing agent. They are especially amenable in multi-step ALD processes where surface-ligand exchange and conversion (reduction) occurs. Molybdenum hexacarbonyl (Mo(CO)₆) is an example of a molybdenum complex existing in the oxidation state of zero.

A general structure for low valent molybdenum precursors having one molybdenum is MoLₙ (Formula I), and general structures for low valent molybdenum precursors with two molybdenum atoms are Mo₂Lₙ (Formula II) or LₙMo(L′)ₘMoLₙ (Formula III). For any of Formulas I-III, each L is independently a monodentate ligand, ambidentate ligand, bidentate ligand or tridentate ligand and n is an integer of 2 to 6. For Formula III, L′ is a linking moiety such as a bidentate ligand; and m is an integer of 1 to 3.

### Monodentate Ligands

Suitable ligands for the low valent molybdenum complexes include monodentate ligands, also referred to as unidentate ligands. A monodentate ligand is one which binds or coordinates to a metal center via one coordination site of the metal only, or via one site of the ligand only. They may include a wide variety of substituents such as hydrogen, halo, hydroxy, alkyl silyl, silylalkyl, alkenyl, alkynyl, allyl, alkoxy, alkenoxy, alkynoxy, thioalkoxy, aliphatic acyl, —CF₃, nitro, amino, imino, —N(C₁-C₃ alkyl)C(O)(C₁-C₃ alkyl), —C₁-C₃ alkylamino, alkenylamino, alkynylamino, di(C₁-C₃ alkyl)amino, —C(O)O—(C₁-C₃ alkyl), —C(O)NH—(C₁-C₃ alkyl), —CH═NOH, —P(C₁-C₃ alkyl)₃, —PO₃H₂, —OPO₃H₂, —C(O)N(C₁-C₃ alkyl)₂, haloalkyl, alkoxycarbonyl, alkoxyalkoxy, carboxaldehyde, carboxamide, cycloalkyl, cycloalkenyl, cycloalkynyl, aryl, aroyl, aryloxy, arylamino, biaryl, thioaryl, heterocyclyl, alkylheterocyclyl, heterocyclylalkyl, heterocycloyl, alkylaryl, alkylcarbonyl, CO, ═O, ═S, ≡N, ≡CR, ═CR2, —NO, aralkenyl, aralkyl, sulfonyl, sulfonamido, sulfonimido, carbamate, aryloxyalkyl, carboxyl, carboxy, —C(O)NH(benzyl), amido, azido, isocyanato, thiocyanato, isothiocyanato, cyano, isocyano or cyclyl groups where each R is independently an aliphatic such as haloalkyl or aryl such as a haloaryl group.

In some embodiments, the low valent molybdenum precursors include at least one OR, P(R)₃, CNR, allyl or aryl group, where each R is independently an aliphatic, aryl, haloalkyl or haloaryl group.

In some embodiments, the monodentate ligand can include an oxygen atom. In particular embodiments, one or more ligands can be optionally substituted alkoxy. Non-limiting ligands include, e.g., methoxy, ethoxy, isopropoxy (i-PrO) and t-butoxy (t-BuO). Non-limiting molybdenum-containing precursors include, e.g., Mo(CH₂F)(t-BuO)₃, Mo(CF₃)(t-BuO)₃, Mo(CH₂I)(t-BuO)₃, Mo(Cl₃)(t-BuO)₃, Mo(CH₂CH₂F)(t-BuO)₃, Mo(CH₂CH₂I)(t-BuO)₃, Mo(CH₂F)₂(t-BuO)₂, Mo(CF₃)₂(t-BuO)₂, Mo(CH₂I)₂(t-BuO)₂, Mo(Cl₃)₂(t-BuO)₂, Mo(CH₂CH₂F)₂(t-BuO)₂, Mo(CH₂CH₂I)₂(t-BuO)₂, Mo(t-BuO)₂, Mo(CH₃)(t-BuO)₃, Mo(CH₂CH₃)(t-BuO)₃, Mo(CH═CH₂)(t-BuO)₃, Mo(CH═CHCH₃)(t-BuO)₃, Mo(CH₂—CH═CH₂)(t-BuO)₃, Mo(C≡CH)(t-BuO)₃, Mo(C≡CCH₃)(t-BuO)₃, Mo(CH₂C≡CH)(t-BuO)₃, or Mo(acac)₂.

In certain embodiments, the oxygen-containing monodentate ligand may be —OC(CH₃)(CF₃)₂, —OC(CH₃)₂(CF₃), —OC(CH₃)₃, —OSiR₃ (such as —OSiPh₃), C≡O (carbonyl ligand) or —OAr (where Ar groups include but are not limited to phenyl, mesitylenyl, 2,6-iPr₂C₆H₃, hexa-iso-propyl-ter-phenyl, and 2,3,5,6-Ph₄C₆H). In certain embodiments, the oxygen-containing ligand is an ether, epoxide, or ketone. In some cases, the oxygen-containing ligand may be a silyloxy group.

In certain embodiments, the ligand is a phosphorous-containing ligand. Suitable complexes may be of the formula R³P where R is a halo, aliphatic or aryl group. Examples include secondary or tertiary organophosphines such as P (t-Bu)₃, PMe₃, PPh₃, P(OMe)₃, P(OEt)₃, PCl₃ or PF₃. In some embodiments, the phosphorus containing ligand is phosphanetriyltris(benzene sulfonic acid). Other phosphorus containing ligands include —CH₂P(CH₃)₃, —P(O)OH, —P(O)(OCH₃)₂, —P(O)(OCH₂CH₃)₂, and —CH(Si(CH₃)₃)(P(CH₃)₃).

In some embodiments, the ligand is an isocyano functional group, including isonitriles of the formula-C≡NR, such as isocyanoalkyl, isocyanohaloalkyl, isocyanoaryl, isocyanohaloaryl. In some embodiments, R is an aliphatic group such as a haloalkyl, or an aryl group such as haloaryl. In certain embodiments, R may be —CH₂CF₃, —C(F)═CF₂, —C(F)═C(F)CF₃, —CF₂C(F)═CF₂, —CH(CF₃)₂, —CH(CH₃)(CF₃), or —C(CH₃)₂(CF₃). In certain embodiments, R is a perfluoroalkyl substituent of one to ten carbon atoms such as perfluorinated methyl, ethyl, i-propyl, n-propyl, t-butyl, sec-butyl, n-butyl, cyclopentyl, n-pentyl, cyclohexyl or n-hexyl group.

In some embodiments, the monodentate ligand is one with sp² hybridized character such as an allyl, allenyl, ethenyl, indenyl or cyclopentadienyl group. Two of the same such substituents or two different such substituents may be utilized to form precursors with a sandwich structure. In some embodiments, one such substituent is utilized to form a half-sandwich complex. In certain embodiments, the ligand may be mesitylenyl, tolyl, xylyl, benzyl, anilinyl, N,N-dimethylanilinyl, tetrahydrofuranyl, piperidinyl, pyrrolyl, pyrrolidinyl, pyridinyl, piperidinyl, imidazolyl, or pyrimidinyl.

In some embodiments, the ligand is an atom which is connected directly to molybdenum via a multiple bond such as a double or triple bond. Examples include ═O, ═NR, ═S, EN, —CR₂ or ═CR, where each R is independently an aliphatic, aryl, haloalkyl or haloaryl group.

In some embodiments, the molybdenum-containing precursor has at least one optionally substituted haloalkyl group. Non-limiting haloaliphatic group ligands include —CX H_{3-y}, wherein y is 1, 2, or 3, and wherein each X is, independently, halo (F, Cl, Br, or I); —CX_{y}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; or —CH₂CX_{y}H_{3-y}, wherein y is 1, 2, or 3, and wherein each X is, independently, halo (F, Cl, Br, or I). Yet other non-limiting haloalkyl groups include fluoromethyl (—CH₂F), difluoromethyl (—CHF₂), trifluoromethyl (—CF₃), chloromethyl (—CH₂Cl), dichloromethyl (—CHCl₂), trichloromethyl (—CCl₃), bromomethyl (—CH₂Br), dibromomethyl (—CHBr₂), tribromomethyl (—CBr₃), iodomethyl (—CH₂I), diiodomethyl (—CHI₂), triiodomethyl (—CI₃), bromofluoromethyl (—CHFBr), chlorofluoromethyl (—CHFCl), fluoroiodomethyl (—CHFI), 2-fluoroethyl (—CH₂CH₂F), 2-chloroethyl (—CH₂CH₂Cl), 2-bromoethyl (—CH₂CH₂Br), 2-iodoethyl (—CH₂CH₂I), 2,2-difluoroethyl (—CH₂CHF₂), 2,2-dichloroethyl (—CH₂CHCl₂), 2,2-dibromoethyl (—CH₂CHBr₂), 2,2-diiodoethyl (—CH₂CHI₂), 2,2-fluoroiodoethyl (—CH₂CHFI), and the like. In particular embodiments, the C₁₋₂ haloalkyl includes β-halo-substituted ethyl. Yet other haloaliphatic groups include C₁₋₄ haloalkyl, C₂₋₄ haloalkenyl, and C₂₋₄ haloalkynyl.

In other embodiments, the ligand is an optionally substituted alkyl group, optionally substituted alkenyl, or optionally substituted alkynyl. Non-limiting groups include —CₙH₂ₙ₋₁, in which n is 1 or 2; —CₙH₂ₙ₋₁, in which n is 2, 3, or 4; or —CₙH₂ₙ₋₃, in which n is 2, 3, or 4. Yet other non-limiting groups include methyl (—CH₃), ethyl (—CH₂CH₃), vinyl or ethenyl (—CH═CH₂), 1-propenyl (—CH═CHCH₃), allyl or 2-propenyl (—CH₂—CH—CH₂), 1-butenyl (—CH═CHCH₂CH₃), 2-butenyl (—CH₂CH—CHCH₃), 3-butenyl (e.g.—CH₂CH₂CH═CH₂), ethynyl (—C≡CH), 1-propynyl (—C≡CCH₃), 2-propynyl or propargyl (—CH₂C≡CH), 1-butynyl (—C≡CCH₂CH₃), 2-butynyl (—CH₂C≡CCH₃), 3-butynyl (—CH₂CH₂C≡CH), 2-methyl-1-propenyl (CH═C(CH₃)₂, isopropenyl (C(CH₃)—CH₂, 1-methylallyl (CH(CH₃)CH═CH₂ and the like.

In some embodiments, the monodentate ligand may be —CH₂P(CH₃)₃, —CH(Si(CH₃)₃)(P(CH₃)₃), —C(O)C₃F₇, or —CHCHSO₂C₆H₅.

In some embodiments, the monodentate ligand includes a sulfur atom. In particular embodiments, one or more monodentate ligands can be —SO₂CF₃, —SO₂C₃N₂H₃, —CHCHSO₂C₆H₅, —SO₂OCH₃, or —SO₂C₆H₄CH₃.

In some embodiments, the monodentate ligand includes a nitrogen atom. In particular embodiments, one or more monodentate ligands can be optionally substituted amino or optionally substituted bis(trialkylsilyl)amino. Non-limiting ligands can include, e.g., —NMe₂, —NEt₂, —NMeEt, —N(t-Bu)-[CHCH₃]₂—N(t-Bu)-(tbba), —N(SiMe₃)₂, and —N(SiEt₃)₂.

In some embodiments, the optionally substituted amino is —NR¹R², in which each R¹ and R² is, independently, H or alkyl; or in which R¹ and R², taken together with the nitrogen atom to which each are attached, form a heterocyclyl group, as defined herein. In other embodiments, the optionally substituted bis(trialkylsilyl)amino is —N(SiR¹R²R³)₂, in which each R¹, R², and R³ is, independently, alkyl. In yet other embodiments, the optionally substituted trialkylsilyl is —SiR¹R²R³, in which each R¹, R², and R³ is, independently, alkyl.

In other embodiments, the low valent molybdenum precursor includes a first ligand that is —NR₁R² and a second ligand that is —NR₁R², in which each R¹ and R² is, independently, H or alkyl. In yet other embodiments, the formula includes a first ligand that is —OR¹ and a second ligand that is —OR¹, in which each R¹ is, independently, H or alkyl.

In some embodiments, the monodentate ligand is optionally substituted alkyl. Non-limiting alkyl groups include, e.g., CₙH₂ₙ₋₁, where n is 1, 2, 3, or greater, such as methyl, ethyl, n-propyl, isopropyl, n-butyl, isobutyl, s-butyl, or t-butyl. In various embodiments, the ligand has at least one beta-hydrogen or beta-halogen.

In some embodiments, at least one monodentate ligand is optionally substituted haloalkyl. Non-limiting haloalkyl groups include, e.g., CₙH_{2n+1-z}X_{z}, wherein n is 1, 2, 3, or greater; wherein z is 1 to 2n+1 (e.g., 1 to 3, 1 to 5, or 1 to 7); and wherein each X is, independently, halo (F, Cl, Br, or I).

In some embodiments, at least one monodentate ligand is optionally substituted alkenyl or optionally substituted alkynyl. Non-limiting alkenyl groups include, e.g., CₙH₂ₙ₋₁, where n is 2, 3, 4, or greater, such as ethenyl, 1-propenyl, 2-propenyl, 1-butenyl, 2-butenyl, or 3-butenyl. Non-limiting alkynyl groups include, e.g., CₙH₂ₙ₋₃, where n is 2, 3, 4, or greater, such as ethynyl, 1-propynyl, 2-propynyl, 1-butynyl, 2-butynyl, or 3-butynyl.

Alkynyl groups are also suitable monodentate ligands in certain embodiments. In some embodiments, the carbon-carbon triple bond is not bound directly to the molybdenum, for example in a formula R¹CCCH₂MoL₃ where R¹ is a C₁-C₂ linear or branched alkane such as methyl or ethyl; and L is an amino (dimethylamino, diethylamino, ethylmethylamino, methylpropylamino, aminiocyclopentane, aminocyclohexane) or alkoxy group (methoxy, ethoxy, n-propoxy, isopropoxy, t-butoxy, sec-butoxy, or n-butoxy).

Alkyne compounds which have a carbon-carbon triple bond directly bonded to the molybdenum atom will hydrolyze in the presence of water similar to, although much slower than, amino and alkoxy groups. Therefore, compounds such as (R¹C≡C)₃MoR² and (R¹C≡C)₄Mo where R¹ is a simple alkane such as methyl or ethyl, and R² is a C₁-C₂ hydrocarbon are precursors having monodentate ligands in accordance with certain embodiments. In compound (R¹C≡C)₃MoR² the molybdenum center has three alkynes with the carbon-carbon triple bond bonded to the molybdenum center. Tetra-alkynes such as those shown for (R¹C≡C)₄Mo.

In some embodiments, the monodentate ligand is halo. In particular, the metal-containing precursor can be a metal halide or organometal halide. Non-limiting metal halides and organometal halides include FCH₂MoX₃, CF₃MoX₃, ICH₂MoX₃, CI₃MoX₃, CH₂FCH₂MoX₃, CH₂ICH₂MoX₃, MoX₂, or MoX₄, in which each X is, independently, halo. In other embodiments, the metal-containing precursor is RMoX₃, in which R is C₁₋₄ haloalkyl, C₂₋₄ haloalkenyl, or C₂₋₄ haloalkynyl; and in which each X is, independently, halo. In yet other embodiments, the metal-containing precursor is RMoX₃, in which Ris C₁₋₂ alkyl, C₂₋₄ alkenyl, or C₂₋₄ alkynyl; and in which each X is, independently, halo.

In other embodiments, the monodentate ligand is C₁-C₃ aliphatic (wherein the C₁-C₃ aliphatic may be optionally substituted with a ketone, an alkoxy group, an epoxy group) or a —C(O)C₁-C₃ alkyl group. Ethers, ketones or epoxide-containing ligands on the low valent molybdenum-containing precursors may be advantageous to assist in crosslinking.

In some embodiments, the monodentate ligand can include a silicon atom. In some embodiments, the monodentate ligand may be —Si(CH₃)₃, —Si(C₂H₅)₃, —CH₂Si(CH₃)₃, —CH(Si(CH₃)₃)₂ or —C(Si(CH₃)₃) 3. In particular embodiments, one or more ligands can be optionally substituted trialkylsilyl or optionally substituted bis(trialkylsilyl)amino. Non-limiting ligands can include, e.g., —SiMe₃, -SiEt₃, —N(SiMe₃)₂, and —N(SiEt₃)₂.

For any formula herein, each monodentate ligand may independently be hydrogen, halo, azido, cyano, alkylcarbonyl, isothiocyanato, thiocyanato, optionally substituted alkyl, optionally substituted aryl, optionally substituted amino, optionally substituted bis(trialkylsilyl)amino, optionally substituted trialkylsilyl, or optionally substituted alkoxy (e.g., —OR¹, in which R¹ can be alkyl).

The present disclosure also encompasses hydrogen as a monodentate ligand. An example of a complex having a hydrogen monodentate ligand is a molybdenum hydride precursor such as Mo(Cp)₂H₂, where Cp is cyclopentadienyl.

The monodentate ligand may be an ambidentate ligand, which has two potential donor atoms, but only attaches to a metal via one of the two. In certain embodiments, the ambidentate ligand is NO₂⁻, which may bond to a metal through either the nitrogen atom or the oxygen atom.

### Bidentate Ligands

Suitable ligands for the low valent molybdenum complexes include bidentate ligands. A bidentate ligand (also referred to as a chelating ligand) is one which binds or coordinates to a metal center via two coordination sites of the metal, or via two sites of the ligand. Bidentate ligands are Lewis bases that donate two pairs of electrons to a metal atom. The bidentate ligands may be neutral or anionic. Furthermore, the bidentate ligands may have the same two coordination atoms, or may be unsymmetrical bidentate ligands, where the two coordination atoms are not the same. In some embodiments, the bidentate ligands may be ethylenediamine (en), bipyridyl (bpy), 1,2-bis(dimethylphosphino) ethane (dmpe), phenanthroline (phen), 1,2-bis(diphenylphosphino) ethane (dppe), acetate (OAc), oxalate (ox), or acetylacetonate (acac). Precursors with bidentate ligands include, but are not limited to, molybdenum diacetylacetonate dioxide (MoO₂(acac)₂).

Example structures containing the bidentate ligand include, but are not limited to

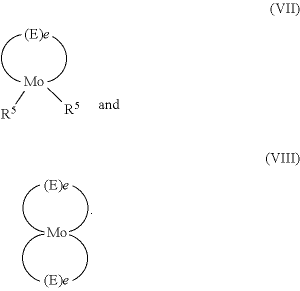

The bidentate ligand may be a linking moiety L′ of the structure -(E)ₑ- where each E independently includes NR, C(R)ₙ, Si(R)ₙ, S, O or P(R)ₙ; each R independently includes hydrogen, aryl, amino or aliphatic; n is 0, 1 or 2 and e is 1, 2, 3, 4 or 5.

Suitable low valent molybdenum precursors may contain one, two or three bidentate ligands each of which may be the same or different.

The bidentate ligand may be an amidinate, an amidate, an iminopyrrolidinate, a diazabutadiene, a beta-imino amide, an alpha-imino alkoxide, a beta-diketiminate, a beta-ketoiminate, a beta-diketonate, a pyrazolate, a beta-amino alkoxide, a guanidinidate, a dithiolene, an alpha-iminothiolene, an alpha-dithiolate, or a beta-dithiolate. Other examples of suitable materials include the bidentate ligands described in US 2022/0170155 and WO 2021/035236, which are incorporated herein by reference in their entireties.

### Tridentate Ligands

A tridentate ligand is one with three atoms that can function as acceptors in a coordination complex. In certain embodiments, the tridentate ligand three nitrogen, three sulfur, three phosphorus or three oxygen atoms available for chelation. Tridentate ligands include cis,cis -1,3,5-triaminocyclohexane, 1,4,7-triazacyclononane, 1,4,7,-trimethyl-1,4,7-triazacyclononane, 1,4,7-trithiacyclononane, bis(diphenylphosphinoethyl)phenylphosphine, N,N,N′,N″N″-pentamethyldiethylenetriamine, tris(4S-isopropyl-2-oxazolinyl)phenylborate, tris(4,4-dimethyl-2-oxazolinyl) phenyl borate, trispyrazolylborate, 1,4,7-trioxonane, diethylenetriamine, or an iminodiacetate anion. Suitable low valent molybdenum precursors may contain one, two or more tridentate ligands which may be the same or different.

The low valent molybdenum precursors may have two to six ligands. Each occurrence of L may independently be a monodentate, ambidentate, bidentate or tridentate ligand as described above. Low valent molybdenum precursors having two ligands may be of the formula MoL₂.

Precursors with two ligands include, but are not limited to, bis(ethylbenzene) molybdenum (C₁₆H₂₀Mo).

FIG. 2B illustrates example structures for molybdenum precursors having three ligands (Formula XIV), four ligands (Formula V and Formula VI) or five ligands (Formula IX and Formula X) in certain embodiments. For Formulas XIV, VI, IX and X_{y}R⁴, R⁶, R⁷ and R¹⁵ are each independently-CH₃, —C₂H₅, —C₃H₇, —C₄H₉, —CH₁₁, —CF₃, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃ or —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, —P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃, or —SO₂C₆H₄CH₃. For Formula IX_{y} G may be ═O, ═NR, ═S or ═CR₂, where each R is independently an aliphatic, aryl, haloalkyl or haloaryl group. Suitable precursors having four ligands include, but are not limited to, Mo(NtBu)₂(OBu)₂ and (iPrCp)₂MoH₂. Suitable precursors having five ligands include, but are not limited to, MoO(OiPr)₄.

For Formula X_{y} each R⁸ is independently any of the monodentate, ambidentate or bidentate ligands described above. For Formula V, R¹ may be aliphatic, R² may be any of the monodentate, ambidentate, bidentate or tridentate ligands described above, and n may be 1, 2, 3, 4 or 5.

Low valent molybdenum precursors may also have six ligands. Precursors with six ligands include, but are not limited to, molybdenum hexafluoride (MoF₆) and molybdenum hexacarbonyl (Mo(CO)₆). In some embodiments, such precursors may have the general formula Mo(X)ₚ (R¹⁰)_{q} (XII) where each X independently includes chloro, fluoro, bromo or iodo; each R¹⁰ independently includes allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR¹¹, where R¹¹ includes aliphatic, aryl or heterocyclyl; p is 1 to 4; q is 2 to 5; and p+q=6.

Low valent molybdenum precursors having six ligands may also be of the formula the Formula (XIII): Mo(R¹²), (R¹³)ₛ (XIII) where each R¹² independently includes allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR¹⁴, where R¹⁴ includes aliphatic, aryl or heterocyclyl; each R¹³ independently includes trimethylphosphine, triethylphosphine, tri-i-propyl phosphine, triphenylphosphine, tris(trimethylsilyl)phosphine, tris(2-carboxyethyl) phosphine, tris(dimethylamino)phosphine, tris(o-tolyl)phosphine, tris(4-methoxyphenyl)phosphine or tris(2-furyl)phosphine; r is 1 to 6; s is 0 to 5; and r+s=6.

FIG. 2C illustrates example structures for low valent molybdenum precursors having six ligands. Structures 1-9 have one or more CNR ligands which may be isocyanoalkyl, isocyanohaloalkyl, isocyanoaryl, or isocyanohaloaryl groups. In some embodiments, R is an aliphatic group such as a haloalkyl, or an aryl group such as haloaryl. In certain embodiments, R may be —CH₂CF₃, —CH(CF₃)₂, —CH(CH₃)(CF₃), or —C(CH₃)₂(CF₃). In certain embodiments, R is a perfluoroalkyl substituent of one to ten carbon atoms such as perfluorinated methyl, ethyl, i-propyl, n-propyl, t-butyl, sec-butyl, n-butyl, cyclopentyl, n-pentyl, cyclohexyl or n-hexyl group. Structures 10-18 have one or more PMe₃ ligands.

Molybdenum complexes can be prepared using a zero valent starting material such as molybdenum hexacarbonyl. Other synthetic routes include reaction of MoCl₃ (THF)₃ with the appropriate ligand followed by reduction and reaction of MoX₅ (X═C₁, Br, I) with the appropriate ligand followed by reduction.

The starting material can be treated with a neutral ligand, such as a thioether (dialkylsulfide), to induce redox neutral ligand exchange. The zero valent starting material can also be treated with a ligand precursor, such as bis(diethylthiocarbamoyl)disulfide or bis(trifluoromethyl)-1,2-dithiete, to induce oxidative addition and form the sulfur-containing complexes described herein.

The reactions may be conducted in a variety of non-protic solvents. For example the reaction may be conducted in an ether solvent, such as tetrahydrofuran, 2-methyltetrahydrofuran, diethyl ether, methyl-tert-butyl ether, 1,2-dimethoxyethane, in a hydrocarbon solvent such as toluene, benzene, heptane, hexane, pentane, or in a halocarbon solvent such as chlorobenzene, dichlorobenzene, fluorobenzene, difluorobenzene, dichloromethane, chloroform, etc. The reactions can be conducted in a wide temperature range depending on the boiling point of the solvent and on solubility of the products. In some embodiments, the starting materials, reaction intermediates, and the desired products are unstable toward moisture and oxygen. Accordingly, the reaction process should be conducted using anhydrous and air-free conditions using a protective inert gas, such as nitrogen or argon.

### Dimolybdenum Complexes

In another aspect, precursors for deposition of molybdenum-containing films are di-molybdenum compounds containing a direct molybdenum-molybdenum bond (e.g., a multiple molybdenum-molybdenum bond, such as a double bond, or any multiple bond with a bond order of 2-5). The directly bonded dimolybdenum precursors may be of the structure Mo₂Lₙ (II), where each occurrence of L is independently a monodentate, ambidentate, bidentate or tridentate ligand as described above, and n is 2 to 6. One example precursor is Mo₂(O-isopropyl) 6. Other example precursors are shown in FIG. 2D. In some embodiments, the dimolybdenum precursor has molybdenum atoms directly connected by a double bond (such as structure 19). In some embodiments, the dimolybdenum precursor has molybdenum atoms directly connected by a triple bond (such as structures 20-23). For structures 20 and 21, R may be an aliphatic group such as an alkyl group, a haloalkyl group or a silyl group. For structure 23, L may be any ligand described above, or may be any one of CO, CNR or PMe₃ (where R is aliphatic, aryl or heterocyclyl) and X is halo. Such precursors are particularly useful for deposition of molybdenum metal and high purity molybdenum metal because it may be easier to reduce such compounds to metallic molybdenum than some monoatomic molybdenum compounds.

Di-molybdenum precursors described herein can be synthesized using dimolybdenum tetraacetate as a starting material by treatment with a ligand salt such as lithium amidate. In one aspect, a container housing any of the precursors described herein in a solid or liquid form is provided. In another aspect a solution of any of these precursors is provided, where the solvent may include, for example, a high boiling point hydrocarbon solvent, such as a higher alkane. In some embodiments a container holding the molybdenum precursor (in solid or liquid form or in solution) is filled with an inert gas, such as nitrogen (N₂), or argon (Ar), to prevent contact of the precursor with air, and possible decomposition due to contact with moisture and/or air. In some embodiments the container is adapted for vaporization of the precursor inside the container. For example, the container may include an inlet and an outlet, where the inlet is adapted to be connected with a source of a carrier gas that can be flowed over or through the precursor thereby assisting in precursor vaporization. The outlet is adapted for removing the carrier gas and the precursor vapor from the container and is configured to be connected to a conduit that can be used to deliver the precursor vapor to the processing chamber. The inlet and the outlet each has a closed position and an open position, and, for example, can include manual valves that can be used to switch from closed to open positions and back. When the container is stored or transported the inlet and the outlet are closed. When the container is fitted to the deposition apparatus for use, the inlet and the outlet valves may be open, and a carrier gas may be flown into the inlet, and out from the outlet carrying the precursor vapor.

In some embodiments the container has a flow-over design, in which the inlet and the outlet are positioned above the surface of the precursor. For example, in a cylindrical container the inlet and the outlet may be positioned at a similar vertical elevation (e.g., the vertical distance between the inlet and the outlet may be less than about 20% of the cylinder height). In other embodiments the container has a bubbler design, in which the inlet is positioned below the surface of the precursor and the outlet is positioned above the inlet (e.g., above the surface of the precursor). For example, in a cylindrical container the inlet and the outlet may be positioned far from each other in a vertical direction (e.g., the vertical distance between the inlet and the outlet may be more than about 30%, such as more than about 50%, or more than about 80% of the cylinder height.

A low valent dimolybdenum complex may also contain two molybdenum atoms connected indirectly to each other by a linking moiety. Such precursors may be of the formula LₙMo(L′)ₘMoLₙ (III) where each L is independently a monodentate ligand, ambidentate ligand, bidentate ligand or tridentate ligand as described above; L′ is a linking moiety; n is 2 to 6; and m is 1 to 3. The linking moiety L′ may be of the structure -(E)ₑ- where each E independently includes C(R)ₙ, NR, Si(R)ₙ, S, O or P(R)ₙ; each R independently includes hydrogen, aryl, amino or aliphatic; n is 0, 1 or 2 and e is 1, 2, 3, 4 or 5.

In some embodiments, the low valent dimolybdenum complex may contain two molybdenum atoms both directly bonded to each other and also connected indirectly to each by a linking moiety as described above. Returning to FIG. 2D, example structures 24 and 25 having both types of connections are shown. For structures 24 and 25, L may be any ligand described above, or preferably CO, CNR or PMe₃ (where R is aliphatic, aryl or heterocyclyl) and X is halo.

The molybdenum-containing films, and, particularly, high purity molybdenum metal, provided herein can be used in interconnect metallization (e.g., for filling recessed features to form contacts), in logic gate applications in FinFETs, as adhesion layers or diffusion barriers, and in 3D NAND fabrication. Examples of applications include logic and memory contact fill, DRAM buried wordline fill, vertically integrated memory gate, and wordline fill, and 3-D integration using through-silicon vias (TSV). The resistivity of molybdenum scales better than that of tungsten, and in some embodiments, molybdenum is particularly advantageous metal for filling narrow recessed features, e.g., features with widths of less than about 20 nm.

In one application, molybdenum metal is used for manufacturing barrierless contacts. In this application, molybdenum metal is deposited directly into the recessed features (contact holes) having widths of about 5-100 nm, e.g., about 5-20 nm, where the recessed features are formed in the dielectric layer, and include exposed dielectric, such as silicon oxide, silicon nitride, or a low-k material such as silicon oxycarbide at the sidewalls and exposed silicon or silicon germanium at the bottom. In alternative embodiments, the contact hole prior to deposition may be lined with a barrier layer, such as WN, MoN, MoC, or TiN onto which the molybdenum metal is deposited.

### Copper Precursors

Copper metal can be deposited using a variety of copper precursors, where copper may be in +1 or +2 oxidation states. The precursors may be cuprous (copper (I)) compounds such as acetylacetonates, ketoiminates, diiminates, cyclopentadienyl compounds, amidinates, guanidinates or amides; or cupric (copper (II)) compounds such as acetylacetonates, ketominates or aminoalkoxides. In some embodiments the precursors are coordination complexes, where copper coordinates to a multiple bond such as a double or triple bond; or coordinates to the oxygen of a carbonyl group for example.

Examples of copper precursors include Cu(acac)₂ where acac=acetylacetonato; Cu(thd)₂ where thd=tetrahydrodionato); hexafluoroacetylacteonate-copper-trimethylsilane; cyclopentadienyl (Cp) compounds such as CpCu(CNMe), CpCu(CNCMe₃), CpCuCO, CPCuPR₃ (where R=Me, Et or Ph) and CpCu(CSiMe₃)₂; alkyl or aryl compounds such as MeCu(PPh₃)₃, CuMe, CuCCH(ethynylcopper), CuCMe₃(methylacetylide copper), (H₂C═CMeCC)Cu(3-methyl-3-buten-lynylcopper), CuCCPh, C₆H₅Cu(phenyl copper), (Me)₃CCCCu(3,3-dimethyl-1-butynyl) copper, Me₃SiCCCH₂Cu; and other compounds such as CuCN, [Cu(OAc]ₙ (where OAc=acetate), Cu₂Cl₂(butadiene), C₇H₇CuO (2-methoxyphenylcopper), (MeCN)₄CuX (where X is a halide, an alkyl, an amine or a phenyl group), Me₃SiOCu(PMe₃)₃, Cu(C₄H₄S) and Cu-carbene compounds such as those derived from imidazolium.

### Cobalt Precursors

Cobalt metal can be deposited using a variety of cobalt precursors, where cobalt may be in +1, +2 or +3 oxidation states. Examples of cobalt precursors include cobalt acetate, cobalt acetylacetonates (e.g., cobalt (III) bis(acetylacetonate)), cobalt amidinates (e.g., bis(N-t-butyl-N′-ethylpropanimidamidato) cobalt (II),) cobaltocene, and carbonyl-containing cobalt precursors (e.g., cobalt tricarbonyl nitrosyl, and cyclopentadienylcobalt dicarbonyl). An example of a halogen-containing cobalt precursor is CoCl₂ (TMEDA), where TMEDA is N,N,N′,N′tetramethylethylenediamine.

### Ruthenium Precursors

Ruthenium metal can be deposited, for example, using vaporizable ruthenium precursors, such as bis(ethylcyclopentadienyl) ruthenium (II), bis(pentamethylcyclopentadienyl) ruthenium, ruthenocene, and cyclopentadienylpropylcyclopentadienylruthenium (II).

### Tungsten Precursors

Tungsten can be deposited using a variety of volatile precursors. In some embodiments halogen-containing tungsten precursors, such as WHalₓ, where Hal is a halogen (e.g., F, Cl, Br, and/or I) and x is from 2 to 6, are used. In some embodiments tungsten chloride is used. Tungsten chloride includes tungsten pentachloride (WCl₅), tungsten hexachloride (WCl₆), tungsten tetrachloride (WCl₄), tungsten dichloride (WCl₂), and mixtures thereof. In other examples tungsten fluoride, such as tungsten hexafluoride may be used.

### Additional Precursors

In some embodiments, other useful precursors include vanadium-containing precursors such as tetrakis (dimethylamino) vanadium, tris(dimethylamino)cyclopentadienylvanadium, tetrakis (ethylmethylamino) vanadium; niobium-containing precursors such as (tert-butylimido)bis(diethylamino) niobium, (tert-butylimido)bis(dimethylamino) niobium and (tert-butylimido)bis(ethylmethylamino) niobium; tantalum-containing precursors such as tert-butylimidotris(dimethylamido) tantalum and tantalum pentachloride; iron-containing precursors such as iron (III) tert-butoxide dimer, ferrocene and iron pentcarbonyl; nickel-containing precursors such as allyl (cyclopentadienyl) nickel(II) and nickel(II) bis(acetylacetonate); zinc-containing precursors such as zinc acetate and diethylzinc; and chromium-containing precursors such as chromium carbonyl and bis(cyclopentadienyl) chromium (II).

Returning to FIG. 2A, an iodine-containing reagent is introduced to the process chamber which reacts with the metal-containing precursor in operation 220. The iodine-containing reagent may be hydrogen iodide (HI); iodine (I₂); an alkyl iodide such as CH₃I, C₂H₅I, C₃H₇I, C₄H₉I, CH₂I₂, C₂H₄I₂, C₃H₆I₂ or C₄H₈I₂; an iodosilane such as SiH₃I, SiH₂I₂, SiHI₃, SiI₄ or Si₂I₆; a metal bromide; boron triiodide (BI₃); a metal iodide such as titanium tetraiodide (TiI₄) or aluminum triiodide (AlI₃) or an alkyl iodosilane such as Si(CH₃)I₃, Si(CH₃)₂I₂, Si(CH₃)₃I, Si(CH₃)HI₂, Si(CH₃)₂HI or Si(CH₃)H₂I.

Suitable iodine-containing reagents include, but are not limited to: I₂; HI; CH₃I; CF₃I, C₂H₅I; 1-iodopropane; 2-iodopropane; 1-iodobutane; 2-iodobutane; sec-butyl iodide; t-butyl iodide; iodocyclopentane; iodocyclohexane; diiodomethane; 1,2-diiodoethane; 1,1-diiodopropane; 1,2-diiodopropane; 1,3-diiodopropane; 2,2-diiodopropane; 1,1-diiodobutane; 1,2-diiodobutane; 1,3-diiodobutane; 2,2-diiodobutane; 2,3-diiodobutane; 1,2-diiodo-2-methylpropane; 2,3-diiodo-2,3-dimethylbutane; 1,1,2,2-tetraiodoethane; 2,2,3,3-tetraiodobutane; 1,1,1,2,2,2-hexaiodoethane; 1,2-diiodocyclopentane; 1,2-diiodocyclohexane; iodobenzene; diiodobenzene; 2-iodopyridine; 3-iodopyridine; 4-iodopyridine; 3-iodo-1-nitrobenzene; 3-iodo-1-trifluoromethylbenzene; 4-iodoaniline; 4-iodo-1-dimethylaminobenzene; 4-iodophenol; (trimethylsilyl)methyl iodide; (trimethylsilyl)methyl diiodide; (trimethylsilyl)methyl triiodide; bis(trimethylsilyl)methyl iodide; bis(trimethylsilyl)methyl diiodide; tris(trimethylsilyl)methyl iodide; 1-(trimethylsilyl)-1-iodoethane; 1-(trimethylsilyl)-2-iodoethane; 1-(trimethylsilyl)-1,2-diiodoethane; 1,1-bis(trimethylsilyl)-1,2-diiodoethane; 1,2-bis(trimethylsilyl)-1,2-diiodoethane; CHI₃; CI₄; 1-iodoethene; 1-iodopropane; 2-iodopropane; 1-iodo-1-butene; 1-iodo-2-butene; 2-iodo-1-butene; 2-iodo-2-butene; iodoacetylene; diiodoacetylene; 3,3-dimethyl-1-iodo-but-1-yne; 1,1-diiodoethane; 1,2-diiodoethane; 1,2-diiodopropene; 1,2-diiodo-2-propene; 1,2-diiodobutene; 1,2-diiodo-2-butene; 1,2-diiodo-3-butene; 3,4-diiodocyclohexene; 4,5-diiodocyclohexadiene; 1,2-diiodoacetylene; 1,1,2,2-tetraiodoethene; SiI₄; SiHI₃; SiH₂I₂; SiH₃I; Si(CH₃)I₃; Si(CH₃)₂I₂Si(CH₃)₃I; Si(CH₃)HI₂; Si(CH₃)₂HI; Si(CH₃)H₂I; Si₂I₆; GeI₄; GeHI₃; GeH₂I₂; GeH₃I; AlI₃; BI₃; TiI₄; SnI₄; HfI₄, N-iodosuccinimide; 1,3-diiodo-5,5-dimethylhydantoin; N-iodophthalimide; N-iodosaccharin; 1-chloro-2-iodoethane; IF₅; iodoacetic acid; iodopropynyl butylcarbamate; benzyl iodide; iodoacetone; bromoiodomethane; chloroiodomethane; allyl iodide; 1-iodophenol; 2-iodophenol; 3-iodophenol and combinations thereof.

Without wishing to bound by theory, the iodine-containing reagent may act as a surface ligand exchange catalyst, reacting with the metal-containing precursor to form an iodine bond-containing metal species in situ, within the process chamber.

Non-limiting examples of reactive species constituting a metal-iodine reactive site or an iodine bond-containing reactive species can include radicals, metastables, ions, neutral species, plasma, photons, radiation, excited molecules, excited atoms, or others described herein. In one non-limiting embodiment, the metastable has an energy of about 0.01-1 eV. In another non-limiting embodiment, the ion has an energy of about 100-1000 eV. In yet another non-limiting embodiment, the reactive species has an energy of about 0.01-1000 eV. Any description herein related to radicals and metastables may, in some non-limiting instances, encompass any reactive species described herein. The iodine bond-containing metal species may be any reactive species as defined above including a metal and iodine. When the metal is molybdenum, the iodine bond-containing metal species maybe MoIₓ such as MoI₂ or MoI₃; or reactive Mo—I* sites. Moreover, the reactive species can include molybdenum halides such as MoI₂ or MoI₃.

In operation 230, the iodine-bond containing metal species is exposed to a reducing agent to form a metal-containing film. Suitable reducing agents include, but are not limited to hydrogen (H₂), ammonia (NH₃), ammonia plasma, hydrazine (N₂H₄), an alkylhydrazine such as t-butyl hydrazine (C₄H₁₂N₂), hydrogen atoms, hydrogen plasma, hydrogen radicals, other hydrogen species, an alcohol, an aldehyde, a carboxylic acid, a borane, an amine, silane (SiH₄), disilane (Si₂H₆), trisilane (Si₃H₈), germane (GeH₄), digermane (Ge₂H₆), borane (BH₃), diborane (B₂H₆) and combinations thereof. In addition to the plasmas mentioned, other reducing agents may be provided by generating plasma from one or more the reducing agents listed.

Exposing the substrate to the reducing agent may include contacting the substrate with the reducing agent for a time of between about 0.1 seconds and about 180 seconds; between about 0.5 seconds and 60 seconds; or between about 0.1 seconds at 10 seconds. The flow rate of the reducing agent during the exposure of the substrate may be less than 30 slm, or less than 15 slm, or less than 10 slm, or less than 5 slm, or less than 2 slm or even less than 0.1 slm in some embodiments. The flow rate of the reducing agent may range from about 0.1 to 30 slm, from about 5 to 15 slm, or equal to or greater than 10 slm.

As shown in operation 240, if the film deposited is of adequate thickness, the method is completed and ends. As used herein, “metal-containing film” refers to a film only including metal or a film which contains a metal and additional components. Metal-containing films can be deposited for a variety of semiconductor applications. Therefore, the desired thickness will depend upon the particular application. In some embodiments metal-containing films may be deposited as a conformal layer to a thickness of between about 0.1-10 nm on a substrate.

If a thicker film is desired, operation 250 is a process flow path indicating that after operation 230, operation 210 can commence again, repeating n times. In process flow path 250, n is the number of cycles which may be from 1 to 50 or from 20 to 40. The cycle of operations 210, 220 and 230 can be repeated as many times as necessary. As used herein, the term “cycle” refers to a particular set of sequential operations.

The metal-containing film formed by method 200 may have fewer halogen-based or other impurities than metal-containing films produced by conventional processes at higher temperatures.

In addition to the steps of method 200 as described above, a purge 215 may optionally be performed after operation 210 in some embodiments. A purge 225 may be optionally performed after operation 220 in some embodiments; or both purge 215 and purge 225 may be performed in some embodiments. Purging the chamber may involve flowing a purge gas or a sweep gas, which may be a carrier gas used in other operations or may be a different gas. In some embodiments, purging may involve evacuating the chamber. Examples of purge gases include argon (Ar), nitrogen (N₂), hydrogen (H₂), helium (He), oxygen (O₂), krypton (Kr), xenon (Xe), neon (Ne), and combinations thereof. In various embodiments, the purge gas is an inert gas. The purge gas may include one or more gases. In some embodiments, operations 215 and/or 225 may include one or more evacuation subphases for evacuating the process chamber. Alternatively, it will be appreciated that purges may be omitted in some embodiments. Operations 215 and/or 225 may have any suitable duration, such as between about 0 seconds and about 60 seconds, for example about 0.01 seconds. In some embodiments, increasing a flow rate of one or more purge gases may decrease the duration of a purge. For example, a purge gas flow rate may be adjusted according to various reactant thermodynamic characteristics and/or geometric characteristics of the process chamber and/or process chamber plumbing for modifying the duration of the purge. In one non-limiting example, the duration of a purge phase may be adjusted by modulating purge gas flow rate. This may reduce deposition cycle time, which may improve substrate throughput. After a purge, the organic silicon-containing precursor molecules remain adsorbed onto the substrate surface.

The purge gas can be flowed to a chamber housing the substrate at a flow rate between about 1000 sccm and about 40000 sccm (e.g., about 100 to 2000 sccm). The purge gas can be flowed for any useful period (e.g., about 0.1 to 10 seconds) and any useful pressure (e.g., about 0.5 to 25 Torr).

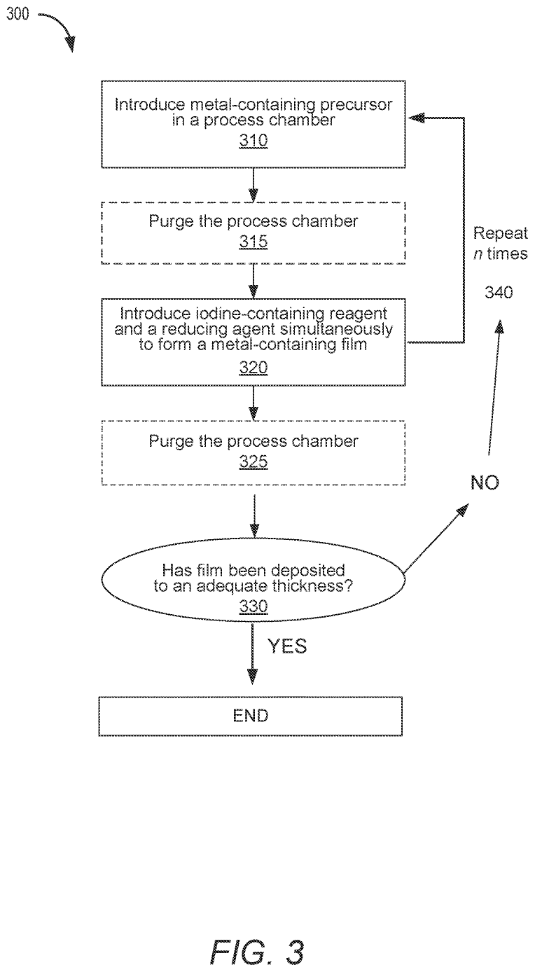

FIG. 3 is a flow chart illustrating method 300, another sequential and optionally cyclic deposition process which begins with operation 310, introduction of a metal-containing precursor in a process chamber. In some embodiments, the metal-containing precursor is a molybdenum-containing precursor, and the deposited metal-containing film is a molybdenum-containing film. Operation 310 is similar to operation 210, discussed above. In method 300, operation 320 is a simultaneous introduction of an iodine-containing reagent and a reducing agent, combining the operations 220 and 230 as described above for method 200. During operation 320, the iodine bond-containing species described above is formed and reduced. Subsequently, the process chamber is purged in operation 325. In operation 330, a determination of whether or not the film deposited is of a desired thickness. If not, the process flow path 340 indicates that a cycle may be repeated n times by returning to and re -running operation 310 n times. In addition, the process chamber may be optionally purged in operation 315 after operation 310.

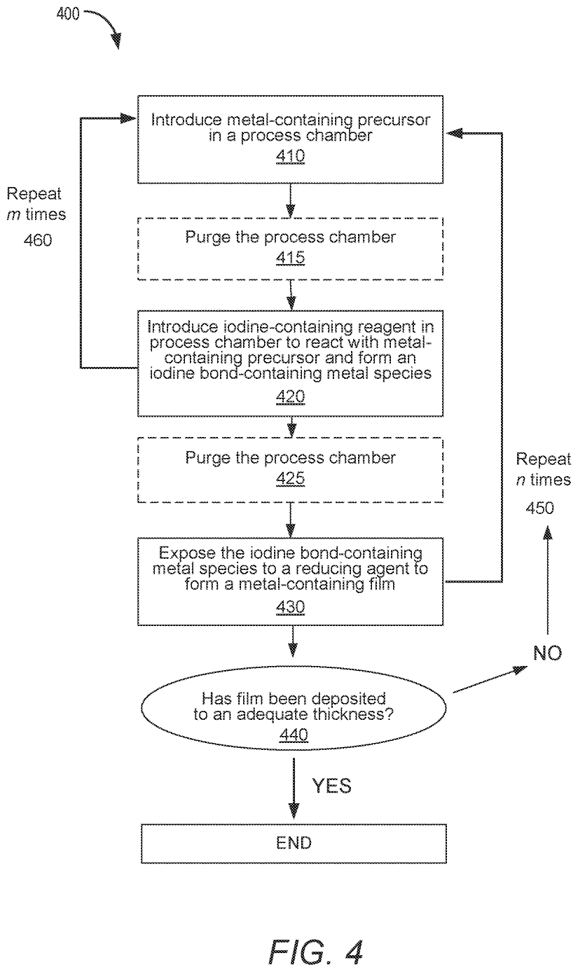

FIG. 4 is a flow chart illustrating method 400, another sequential and optionally cyclic deposition process which begins with operation 410, introduction of a metal-containing precursor in a process chamber. In some embodiments, the metal-containing precursor is a molybdenum-containing precursor, and the deposited metal-containing film is a molybdenum-containing film. Operation 410, the introduction of a metal-containing precursor in a process chamber, is similar to operation 210 as discussed above. In operation 420, the substrate is exposed to an iodine-containing reagent, similar to operation 220 as discussed above. An iodine bond-containing metal species is formed, and then in operation 430 the iodine bond-containing metal species is reduced to form a metal-containing film upon exposure to a reducing agent. A determination 440 is made whether or not the film deposited is of adequate thickness, and if a thicker film is desired, the cycle of process steps 410, 420 and 430 may be repeated n times as illustrated by process flow path 450.

Process flow path 460 illustrates that after operation 420, operation 410 may be repeated m times. In operation 460, m is the number of cycles which may be from 1 to 50 or from 20 to 40. The cycle of operations 410 and 420 can be repeated as many times as necessary. In certain embodiments, the method includes a dual cycle wherein different sets of steps are both repeated. The dual cycle may also be described as a sub-cycle within a cycle as illustrated by process flow path 450 and process flow path 460.

In addition to the steps of method 400 as described above, a purge 415 may optionally be performed after operation 410 in some embodiments. A purge 425 may be optionally performed after operation 420 in some embodiments; or both purge 415 and purge 425 may be performed in some embodiments as discussed above with reference to method 200.

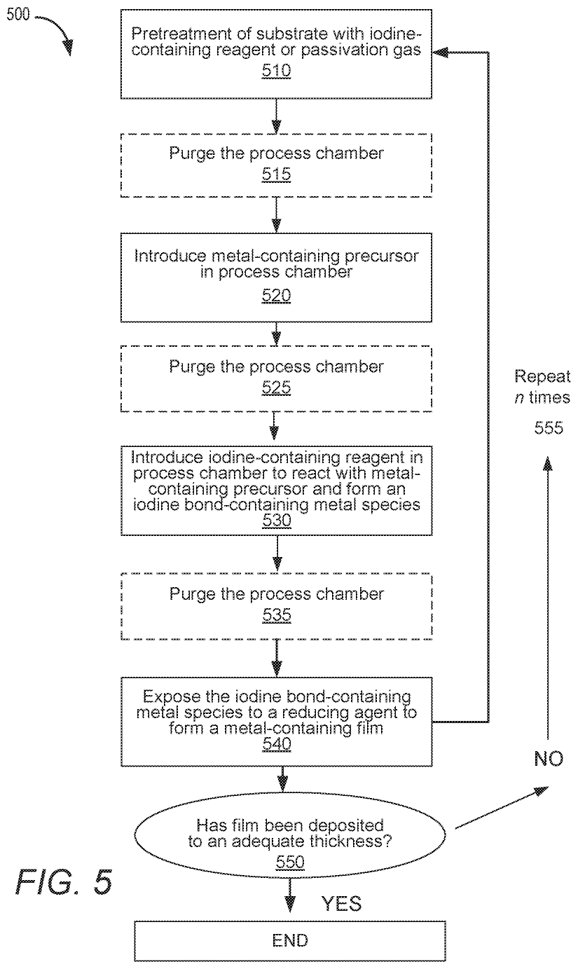

FIG. 5 is a flow chart illustrating method 500, another sequential and optionally cyclic deposition process which begins with operation 510, a pretreatment of the substrate in the process chamber. The pretreatment 510 may constitute exposing the substrate to an iodine-containing reagent or a passivation gas. The pretreatment may prevent nucleation of the metal in certain regions, facilitating deposition first at the bottom of a feature.

Suitable passivating gases include, but are not limited to hydrogen, nitrogen, water, ammonia, oxygen, nitrous oxide (N₂O), nitrogen trifluoride (NF₃) and combinations thereof.

Operation 520 is an introduction of a metal-containing precursor into the processing chamber, as described above with reference to operation 210. In some embodiments, the metal-containing precursor is a molybdenum-containing precursor, and the deposited metal-containing film is a molybdenum-containing film. Then, an iodine-containing reagent is introduced into the processing chamber to react with the metal-containing precursor and form an iodine bond-containing species in operation 530, as described above with reference to operation 220. When an iodine-containing reagent is selected for the operation 510 pretreatment, the iodine-containing reagent selected for operation 530 may be the same or a different iodine-containing reagent. In operation 540, the iodine-bond containing metal species is exposed to a reducing agent to form a metal-containing film, as described for operation 230 above.

As shown in operation 550, if the film deposited is of adequate thickness, the method is completed and ends. If a thicker film is desired, process flow path 555 indicates that after operation 540, operation 510 can commence again, repeating n times. For process flow path 555, n is the number of cycles which may be from 1 to 50 or from 20 to 40. The cycle of operations 510, 520, 530 and 540 can be repeated as many times as necessary to achieve a desired thickness. In addition to the steps of method 500 as described above, a purge 515 may optionally be performed after operation 510 in some embodiments. A purge 525 may be optionally performed after operation 520 in some embodiments and a purge 535 may optionally be performed after operation 530 in some embodiments. In some embodiments, purges 515, 525 and 535 may all be performed during one cycle in as discussed above with reference to method 200.

### Methods with Iodine-Containing Reagent Introduction as First Step

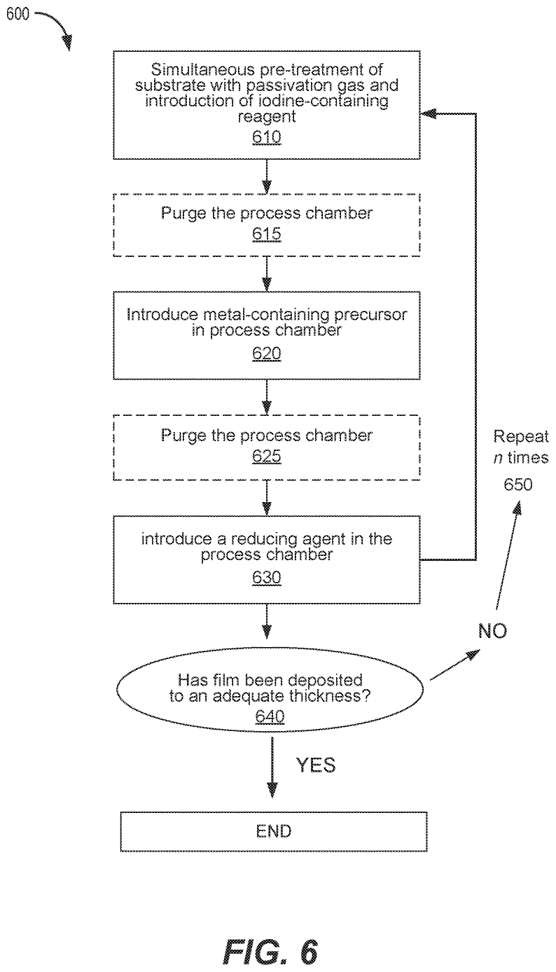

FIG. 6 is a flow chart illustrating method 600, another sequential and optionally cyclic deposition process which begins with operation 610, a pretreatment of the substrate in the process chamber by introduction of a passivation gas and simultaneous introduction of an iodine-containing reagent.

Suitable passivating gases include, but are not limited to hydrogen, nitrogen, water, ammonia, oxygen, nitrous oxide (N₂O), nitrogen trifluoride (NF₃) and combinations thereof.

Operation 620 is an introduction of a metal-containing precursor into the processing chamber, as described above with reference to operation 210. In some embodiments, the metal-containing precursor is a molybdenum-containing precursor, and the deposited metal-containing film is a molybdenum-containing film. In operation 630, a reducing agent is introduced into the process chamber to form a metal-containing film, as described for operation 230 above.

As shown in operation 640, if the film deposited is of adequate thickness, the method is completed and ends. If a thicker film is desired, process flow path 650 indicates that after operation 640, operation 610 can commence again, repeating n times. For process flow path 650, n is the number of cycles which may be from 1 to 50 or from 20 to 40. The cycle of operations 610, 620, and 630 can be repeated as many times as necessary to achieve a desired thickness. In addition to the steps of method 600 as described above, a purge 615 may optionally be performed after operation 610 in some embodiments. A purge 625 may be optionally performed after operation 620 in some embodiments; or both purge 615 and purge 625 may be performed in some embodiments as discussed above with reference to method 200.

### Methods of Forming Molybdenum-Containing Materials

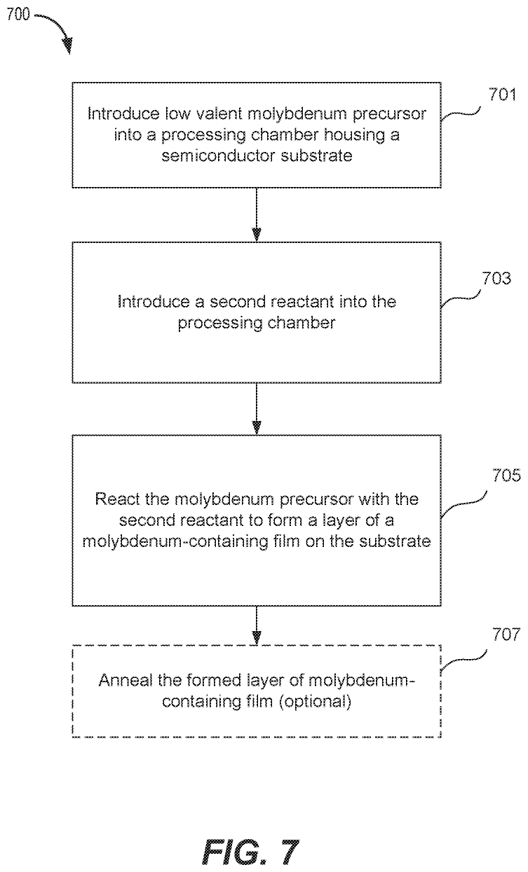

Molybdenum-containing materials can be deposited using the precursors described herein by a variety of deposition methods, such as CVD (including thermal and PECVD), and ALD (including thermal and PEALD). An example method 700 is illustrated by a process flow diagram shown in FIG. 7. The process starts in 701 by introducing a molybdenum precursor described herein into a process chamber housing the semiconductor substrate. The precursor can be introduced in a vaporized form in a flow of inert gas such as argon, helium, or nitrogen (N₂). In operation 703 (which can occur before, after, or during introduction of the molybdenum-containing precursor 701)ₐ second reactant is introduced into the process chamber housing the substrate. In some embodiments, introduction of the molybdenum precursor and of the second reactant is sequential. The chemistry of the second reactant depends on the chemistry of the target molybdenum-containing film. For example, for deposition of molybdenum metal, the second reactant is typically a reducing reactant (including reactants that form a reducing environment upon activation in a plasma). Examples of suitable reactants for forming molybdenum metal include hydrogen (H₂), ammonia (NH₃), hydrazine (N₂H₄), an amine, diborane (B₂H₆), silane (SiH₄), disilane (Si₂H₆), an alcohol, hydrogen sulfide (H₂S), or a thiol. In some embodiments H₂ is a preferred reducing reactant for deposition of molybdenum metal. In some embodiments, the molybdenum-containing precursor is reacted with several reactants sequentially. For example, in some embodiments molybdenum metal is deposited by adsorbing a layer of molybdenum-containing precursor on the substrate, reacting it with a second reactant, and then reacting it with a third reactant.

In one implementation the molybdenum-containing precursor (a first reactant) is first reacted with at least one of water, H₂S, and a thiol (a second reactant). Next, the substrate containing reacted precursor is treated with hydrogen (H₂) (a third reactant). In some embodiments the process chamber is purged and/or evacuated after introduction of each of the reactants. In some embodiments, the first reactant (e.g. water, H₂S, or thiol) is selected such as to facilitate removal of the ligand from the molybdenum precursor, whereas the third reactant (e.g., H₂) is selected to remove the remains of the ligand (e.g., C, N, S, O-containing impurities) from the surface of the substrate and/or to reduce molybdenum to zero oxidation state, and form high purity molybdenum metal.

When molybdenum-containing films, other than molybdenum metal are deposited, the second reactant can be selected such that it serves as a source of necessary elements for the molybdenum-containing film, although in some embodiments these elements may be derived exclusively from the ligand. The process conditions (such as temperature, pressure, reactant flow rates, and optionally, plasma power) can be adjusted to favor a specific film chemistry. For example, borane and silane reactants can be used to deposit molybdenum boride or molybdenum silicide containing materials, in some embodiments, whereas under different conditions, these reactants alone or in combination with other reactants (e.g., H₂) may lead to molybdenum metal. For deposition of molybdenum nitride, nitrogen-containing second reactants may be selected in some embodiments and process conditions can be adjusted to allow inclusion of nitrogen into the film. For example, NH₃, N₂H₄, N₂, alkylamines, and alkylhydrazines may be used as a second reactant, for deposition of molybdenum nitride. For deposition of molybdenum carbide, carbon-containing second reactants may be used and process conditions can be adjusted to allow inclusion of carbon into the film. For example, hydrocarbons may be introduced as the second reactant to form molybdenum carbide. Molybdenum carbonitride films can be formed by introducing nitrogen-containing reactants and/or carbon-containing reactants. In some embodiments the nitrogen-containing and carbon-containing ligands of the molybdenum precursor itself can serve as a source of nitrogen and/or carbon. Molybdenum oxide films can be formed by introducing oxygen-containing second reactants, e.g., O₂, O₃, N₂O, CO₂, etc. The second reactant may be introduced into the processing chamber in a mixture with an inert carrier gas, such as N₂, argon, or helium. Molybdenum sulfide films can be deposited using sulfur-containing reactants or by adjusting process conditions to allow inclusion of sulfur from a sulfur-containing molybdenum precursor into the film. Sulfur-containing reactants include H₂S, dialkylsulfides, dialkyldisulfides and thiols such as methanethiol or tert-butylthiol.

In some embodiments the precursor and the second reactant are allowed to mix in the body of the processing chamber. In other embodiments, after the molybdenum precursor has been introduced and has been adsorbed on the surface of the substrate, the processing chamber is purged with an inert gas and/or evacuated to remove the unadsorbed precursor from the process chamber. In some embodiments the layer of the precursor on the substrate is adsorption-limited. In other embodiments a thicker layer of molybdenum precursor can be formed on the surface of the substrate prior to purging and/or evacuation of the process chamber. It is noted that when the precursor and the second reactant are introduced sequentially, the sequence of introduction of the precursor and of the second reactant may be reversed. In some embodiments the second reactant is introduced first and is allowed to adsorb on the surface of the substrate. Then the process chamber is purged and/or evacuated to remove the second reactant from the volume of the process chamber, and the molybdenum precursor is then introduced.

Referring to operation 705, the molybdenum precursor is reacted with the second reactant to form a layer of a molybdenum-containing material on the substrate, where the reaction occurs on the surface of the substrate and/or in the body of the processing chamber and is optionally assisted by a plasma. For example, in CVD processes the precursor may react with the second reactant in the body of the processing chamber. The reaction may be conducted thermally or with plasma activation. In ALD processes the reaction occurs only on the surface and is limited by the amount of the adsorbed material on the surface (by the amount of molybdenum precursor and/or by the amount of adsorbed second reactant). In surface-limited reactions (such as in ALD) plasma activation is also possible. For example, an adsorbed layer of a molybdenum precursor may be reacted with a plasma formed in a gas that includes a hydrogen-containing second reactant (e.g., H₂, NH₃, CO, alcohol, etc) to form a molybdenum metal layer. Generally, the plasma may be generated directly in the process chamber housing the substrate (direct plasma) or remotely in a separate compartment with the resulting plasma-activated species being fed to the process chamber (remote plasma). The temperature during the reaction process can be, for example, between about 20-600° C. Low temperature deposition at about 450° C. or less such as about 400° C. or less, e.g., between about 100-400° C. is conducted in some embodiments and is particularly advantageous for deposition of molybdenum metal. The pressure in the process chamber can be in a range of between about 0.1-100 Torr, such as between about 0.5-5 Torr in PEALD methods and 1-60 Torr in thermal ALD.

After the reaction is completed, the formed molybdenum-containing layer can be optionally annealed as shown in operation 707. Annealing can be performed by increasing the temperature. For example, if the reaction is conducted at a relatively low temperature, e.g., at a temperature of less than about 450° C., such as less than about 400° C., during the anneal the temperature can be increased e.g., by 50-200° C. In some embodiments, annealing is performed at a temperature of between about 300-500° C.

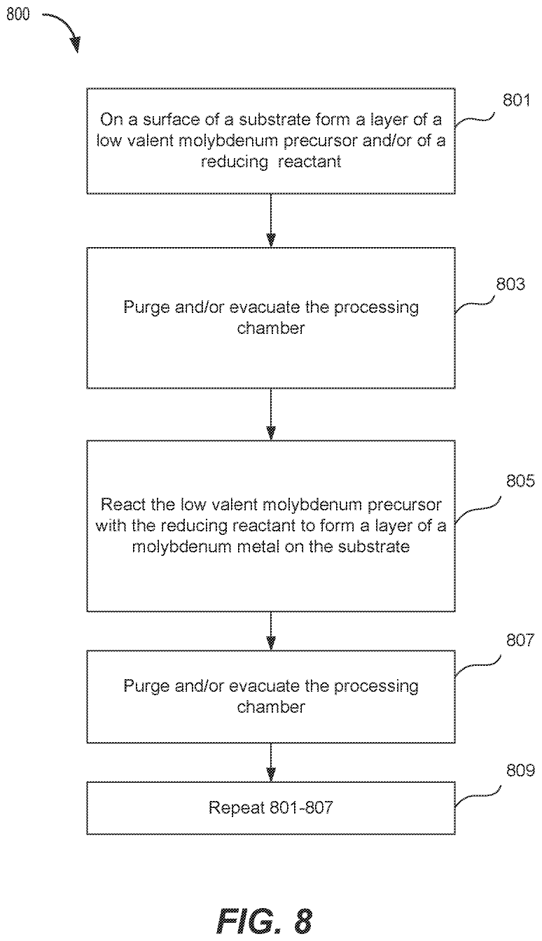

An example of a surface-based deposition process 800 for forming a molybdenum metal film on a substrate is illustrated by a process flow diagram shown in FIG. 8. In operation 801, a layer of a molybdenum precursor and/or of a reducing reactant is formed on a surface of a substrate. In some embodiments the layer is an adsorption-limited layer. Next in operation 803, the processing chamber is purged and/or evacuated. This step ensures that the molybdenum precursor and/or reducing reactant are present only on the surface of the substrate and not in the volume of the processing chamber. Next, in 805 the molybdenum precursor is reacted with the reducing reactant on the surface of the substrate, optionally with plasma activation. For example, if only molybdenum precursor is adsorbed on the surface of the substrate in 801, a reducing reagent may be introduced into the processing chamber and allowed to react with the molybdenum precursor on the surface. If both the molybdenum precursor and the reducing reactant layers are formed on the surface of the substrate in 801, in 803 the process conditions can be adjusted (e.g., using a plasma treatment of the surface, or temperature increase) to activate the reaction. Next, in 807 the processing chamber is purged and/or evacuated, and in 809 operations 801-807 are repeated to form more molybdenum metal. In some embodiments each cycle of operations 801-807 deposits about 0.1-5.0 Å of molybdenum metal on average. In some embodiments 2-100 cycles are performed. For example, 2-20 cycles can be performed. Molybdenum layers of with thicknesses of between about 5-5,000 Å, such as 5-500 Å can be formed with high level of control over layer thickness. This method can be used to form conformal layers of molybdenum metal with excellent step coverage.

Molybdenum-containing films can be deposited on a variety of surfaces including on metals (e.g., copper, nickel, cobalt, tungsten, etc.), dielectrics (e.g., silicon oxide based dielectrics, silicon nitride, silicon carbide, metal oxides, metal nitrides, etc), and on amorphous and crystalline silicon. In some embodiments molybdenum-containing films (e.g., molybdenum metal) are deposited on a substrate containing an exposed layer of dielectric and an exposed layer of metal.

In some embodiments, molybdenum-containing films are deposited selectively on dielectrics in a presence of exposed metal and, in other embodiments, on metals in a presence of exposed dielectrics. “Selective deposition” as used herein refers to deposition on a target surface at a higher rate than on a non-target surface. In some embodiments the selectivity (the ratio of deposition rate on a target surface to the deposition rate on a non-target surface) is greater than 2, such as greater than 5. In some embodiments molybdenum-containing films are deposited on a dielectric (e.g., silicon oxide based dielectric) without being substantially deposited on exposed metal surfaces.

The provided molybdenum-containing films can be deposited on a variety of surfaces including on metals (e.g., copper, nickel, cobalt, tungsten, etc.), dielectrics (e.g., silicon oxide based dielectrics, silicon nitride, silicon carbide, metal oxides, metal nitrides, etc.), and on amorphous and crystalline silicon. In some embodiments the films are deposited as liners or diffusion barrier layers.

In one implementation, provided molybdenum-containing films are used as MOSFET gate electrode materials. In one example, the provided films are integrated into a pMOS device structure. The device (e.g., a transistor) includes a semiconductor layer, a source region, a drain region, and a gate dielectric layer formed over the semiconductor layer and defining a channel region in the semiconductor layer between the source region and a drain region. The semiconductor layer includes a semiconductor material, such as silicon (Si), germanium (Ge), or silicon germanium (SiGe). The gate dielectric layer includes, in one embodiment, a high-k dielectric having a dielectric constant of greater than about 3.9. For example, the gate dielectric layer may include high-k materials, such as HfO, HfSiO, HfSiON, and the like. The gate dielectric layer is typically very thin, e.g., between about 10-15 Å thick. Layers are disposed over the gate dielectric layer, and collectively form the gate electrode. There may be an optional capping layer formed directly over and in contact with the gate dielectric layer. The capping layer includes, in some embodiments TIN, TaN and/or WN, and has a thickness of between about 10-20 Å.

The layer over the capping layer is referred to a work function metal-containing layer. The layer includes a molybdenum-containing material provided herein, where the material has a high work function, such as a work function of greater than about 4.9 eV, greater than about 5.0 eV, or greater than about 5.1 eV. In some embodiments, the layer is a MoN layer having an effective work function of greater than about 5.0. The layer is deposited by ALD or CVD methods described herein, and in some embodiments, is additionally treated with a plasma treatment reactant, to increase its work function.

For example, in some embodiments, the as -deposited molybdenum-containing material is treated with a plasma-activated nitrogen-containing reactant (e.g., N₂) to increase nitrogen content, and work function of the formed layer. The layer, in some embodiments, has a thickness of between about 5-50 Å, or 5-15 Å. In one implementation the work function metal-containing layer has a thickness of about 30 Å. In some embodiments the metal-containing layer is deposited directly onto the capping layer. When the capping layer is absent, the layer may be deposited directly onto the gate dielectric layer. Finally, the device optionally may include one or more conductive layers formed over the metal-containing layer. In some embodiments the conductive layer includes one or more of TiAl, TiAlC, TiAlON, and/or a conductive metal fill, such as Mo, Co, or W.

The provided molybdenum-containing layers may be used in a planar pMOS device, a FinFET pMOS device or in a gate all-around (GAA) pMOS device. Films with work functions of greater than 5.0 eV, such as between about 5.0-5.5 eV, can be obtained.

Molybdenum-containing films can be deposited for a variety of applications in semiconductor processing. In some embodiments molybdenum-containing films (e.g., molybdenum metal) is deposited as a conformal layer to a thickness of between about 0.1-10 nm on a substrate containing one or more recessed or protruding features. In some embodiments recessed features are filled with molybdenum-containing material (e.g., molybdenum metal).

The molybdenum-containing films, and, particularly, high purity molybdenum metal, provided herein can be used in interconnect metallization (e.g., for filling recessed features to form contacts), in logic gate applications in FinFETs, as adhesion layers or diffusion barriers, and in 3D NAND fabrication. Examples of applications include logic and memory contact fill, DRAM buried wordline fill, vertically integrated memory gate, and wordline fill, and 3-D integration using through-silicon vias (TSV). The resistivity of molybdenum scales better than that of tungsten, and in some embodiments, molybdenum is particularly advantageous metal for filling narrow recessed features, e.g., features with widths of less than about 20 nm.

In one application, molybdenum metal is used for manufacturing barrierless contacts. In this application, molybdenum metal is deposited directly into the recessed features (contact holes) having widths of about 5-100 nm, e.g., about 5-20 nm, where the recessed features are formed in the dielectric layer, and include exposed dielectric, such as silicon oxide, silicon nitride, or a low-k material such as silicon oxycarbide at the sidewalls and exposed silicon or silicon germanium at the bottom. In alternative embodiments, the contact hole prior to deposition may be lined with a barrier layer, such as WN, MoN, MoC, or TiN onto which the molybdenum metal is deposited.

### Apparatus

The deposition methods described herein can be carried out in a variety of apparatuses. A suitable apparatus includes a processing chamber having one or more inlets for introduction of reactants, a substrate holder in the process chamber configured to hold the substrate in place during deposition, and, optionally, a plasma generating mechanism configured for generating a plasma in a process gas. The apparatus may include a controller having program instructions for causing any of the method steps described herein. The deposition methods described herein may be carried out in corresponding ALD and CVD apparatuses.

For example, in some embodiments the apparatus includes a controller having program instructions that include instructions for: causing an introduction of a molybdenum precursor to the processing chamber, wherein the precursor is any of the precursors described herein; and causing a reaction between the molybdenum precursor and a second reactant to form a layer of molybdenum-containing material on a substrate. The controller may include program instructions for causing any of the methods described herein.

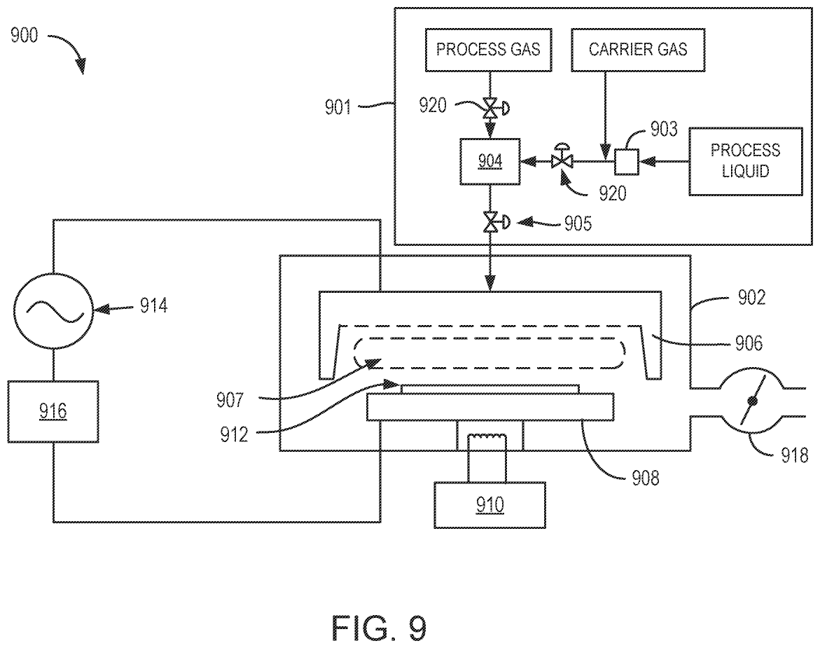

An example of a deposition apparatus suitable for depositing molybdenum-containing films using provided methods is shown in FIG. 9 which schematically illustrates an embodiment of a process station 900 that may be used to deposit material using atomic layer deposition (ALD) and/or chemical vapor deposition (CVD), either of which may be plasma enhanced. For simplicity, the process station 900 is depicted as a standalone process station having a process chamber body 902 for maintaining a low-pressure environment. However, it will be appreciated that a plurality of process stations 900 may be included in a common process tool environment. Further, it will be appreciated that, in some embodiments, one or more hardware parameters of process station 900, including those discussed in detail below, may be adjusted programmatically by one or more computer controllers.

Process station 900 fluidly communicates with reactant delivery system 901 for delivering process gases to a distribution showerhead 906. Reactant delivery system 901 includes a mixing vessel 904 for blending and/or conditioning process gases for delivery to showerhead 906. One or more mixing vessel inlet valves 920 may control introduction of process gases to mixing vessel 904. Similarly, a showerhead inlet valve 905 may control introduction of process gasses to the showerhead 906.

Some molybdenum-containing precursors may be stored in solid or liquid form prior to vaporization and subsequent delivery to the process station. For example, the embodiment of FIG. 9 includes a vaporization point 903 for vaporizing solid reactant to be supplied to mixing vessel 904. In some embodiments, vaporization point 903 may be a heated vaporizer. In some embodiments a flow of an inert gas is passed over the heated solid molybdenum precursor, or bubbled through the heated liquid molybdenum precursor, under sub-atmospheric pressure, and carries the precursor vapor to the process chamber. The precursor vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 903 may be heat traced. In some examples, mixing vessel 904 may also be heat traced. In one non-limiting example, piping downstream of vaporization point 903 has an increasing temperature profile extending from approximately 100° C. to approximately 200° C. at mixing vessel 904.

Showerhead 906 distributes process gases toward substrate 912. In the embodiment shown in FIG. 9, substrate 912 is located beneath showerhead 906, and is shown resting on a pedestal 908. It will be appreciated that showerhead 906 may have any suitable shape and may have any suitable number and arrangement of ports for distributing processes gases to substrate 912. While not explicitly shown, in some embodiments the showerhead 906 is a dual plenum showerhead that includes at least two types of conduits, where the first type of conduit is dedicated to delivery of molybdenum-containing precursor vapor, and the second type of conduit is dedicated to delivery of the second (or other) reactant. In these embodiments the molybdenum-containing precursor and the reactant are not allowed to mix in the conduits prior to entry to the process chamber, and do not share the conduits if delivered to the chamber consecutively.

In some embodiments, a microvolume 907 is located beneath showerhead 906.

Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 908 may be raised or lowered to expose substrate 912 to microvolume 907 and/or to vary a volume of microvolume 907. For example, in a substrate transfer phase, pedestal 908 may be lowered to allow substrate 912 to be loaded onto pedestal 908. During a deposition process phase, pedestal 908 may be raised to position substrate 912 within microvolume 907. In some embodiments, microvolume 907 may completely enclose substrate 912 as well as a portion of pedestal 908 to create a region of high flow impedance during a deposition process.

Optionally, pedestal 908 may be lowered and/or raised during portions the deposition process to modulate process pressure, reactant concentration, etc., within microvolume 907. In one scenario where process chamber body 902 remains at a base pressure during the deposition process, lowering pedestal 908 may allow microvolume 907 to be evacuated. Example ratios of microvolume to process chamber volume include, but are not limited to, volume ratios between 1:700 and 1:10. It will be appreciated that, in some embodiments, pedestal height may be adjusted programmatically by a suitable computer controller.

While the example microvolume variations described herein refer to a height-adjustable pedestal, it will be appreciated that, in some embodiments, a position of showerhead 906 may be adjusted relative to pedestal 908 to vary a volume of microvolume 907. Further, it will be appreciated that a vertical position of pedestal 908 and/or showerhead 906 may be varied by any suitable mechanism within the scope of the present disclosure. In some embodiments, pedestal 908 may include a rotational axis for rotating an orientation of substrate 912. It will be appreciated that, in some embodiments, one or more of these example adjustments may be performed programmatically by one or more suitable computer controllers.

Returning to the embodiment shown in FIG. 9, showerhead 906 and pedestal 908 electrically communicate with RF power supply 914 and matching network 916 for powering a plasma. In other embodiments apparatuses without a plasma generator are used for depositing molybdenum-containing films using provided methods. In some embodiments, the plasma energy may be controlled by controlling one or more of a process station pressure, a gas concentration, a radio frequency (RF) source power, an RF source frequency, and a plasma power pulse timing.

For example, RF power supply 914 and matching network 916 may be operated at any suitable power to form a plasma having a desired composition of radical species. Likewise, RF power supply 914 may provide RF power of any suitable frequency. In some embodiments, RF power supply 914 may be configured to control high- and low-frequency RF power sources independently of one another. Example low-frequency RF frequencies may include, but are not limited to, frequencies between 50 kHz and 700 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some embodiments, pedestal 908 may be temperature controlled via heater 910. Further, in some embodiments, pressure control for deposition process station 900 may be provided by butterfly valve 918. As shown in the embodiment of FIG. 9, butterfly valve 918 throttles a vacuum provided by a downstream vacuum pump (not shown). However, in some embodiments, pressure control of process station 900 may also be adjusted by varying a flow rate of one or more gases introduced to process station 900.

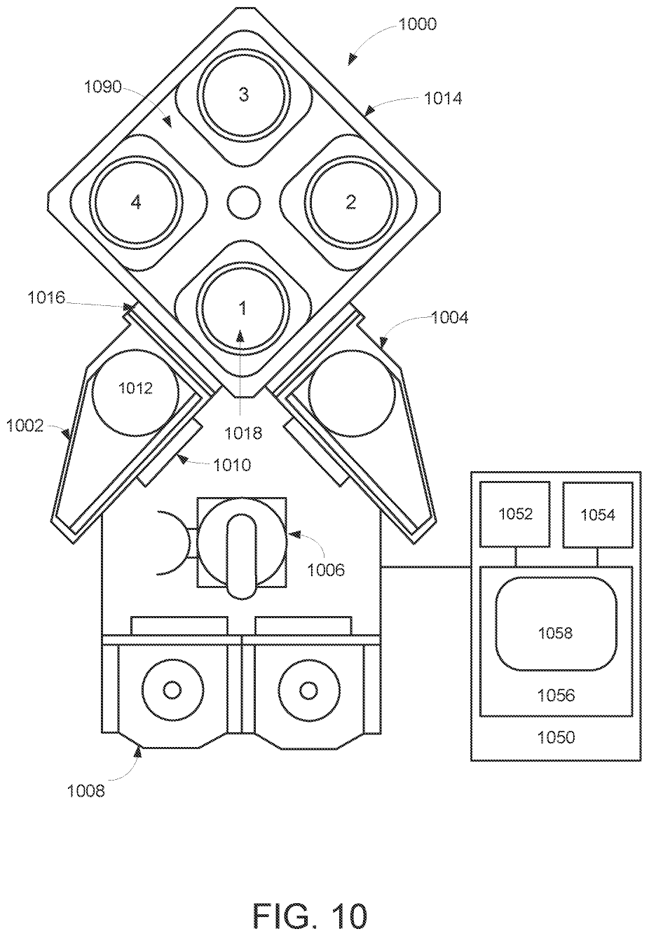

FIG. 10 shows a schematic view of an embodiment of a multi-station processing tool 1000 with an inbound load lock 1002 and an outbound load lock 1004, either or both of which may comprise a remote plasma source. Such tool may be used for processing the substrates using the methods provided herein. A robot 1006, at atmospheric pressure, is configured to move wafers from a cassette loaded through a pod 1008 into inbound load lock 1002 via an atmospheric port 1010. A wafer is placed by the robot 1006 on a pedestal 1012 in the inbound load lock 1002, the atmospheric port 1010 is closed, and the load lock is pumped down. Where the inbound load lock 1002 comprises a remote plasma source, the wafer may be exposed to a remote plasma treatment in the load lock prior to being introduced into a processing chamber 1014. Further, the wafer also may be heated in the inbound load lock 1002 as well, for example, to remove moisture and adsorbed gases. Next, a chamber transport port 1016 to processing chamber 1014 is opened, and another robot (not shown) places the wafer into the reactor on a pedestal of a first station shown in the reactor for processing. While the embodiment depicted in FIG. 10 includes load locks, it will be appreciated that, in some embodiments, direct entry of a wafer into a process station may be provided.

The depicted processing chamber 1014 comprises four process stations, numbered from 1 to 4 in the embodiment shown in FIG. 10. Each station has a heated pedestal (shown at 1018 for station 1), and gas line inlets. It will be appreciated that in some embodiments, each process station may have different or multiple purposes. While the depicted processing chamber 1014 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 10 also depicts an embodiment of a wafer handling system 1090 for transferring wafers within processing chamber 1014. In some embodiments, wafer handling system 1090 may transfer wafers between various process stations and/or between a process station and a load lock. It will be appreciated that any suitable wafer handling system may be employed. Non-limiting examples include wafer carousels and wafer handling robots. FIG. 10 also depicts an embodiment of a system controller 1050 employed to control process conditions and hardware states of process tool 1000. System controller 1050 may include one or more memory devices 1056, one or more mass storage devices 1054, and one or more processors 1052. Processor 1052 may include a CPU or computer, analog and/or digital input/output connections, stepper motor controller boards, etc.

In some embodiments, system controller 1050 controls all of the activities of process tool 1000. System controller 1050 executes system control software 1058 stored in mass storage device 1054, loaded into memory device 1056, and executed on processor 1052. System control software 1058 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 1000. System control software 1058 may be configured in any suitable way. For example, various process tool component subroutines or control objects may be written to control operation of the process tool components necessary to carry out various process tool processes in accordance with the disclosed methods. System control software 1058 may be coded in any suitable computer readable programming language.

In some embodiments, system control software 1058 may include input/output control (IOC) sequencing instructions for controlling the various parameters described above. For example, each phase of an ALD process may include one or more instructions for execution by system controller 1050. The instructions for setting process conditions for an ALD process phase may be included in a corresponding ALD recipe phase. In some embodiments, the ALD recipe phases may be sequentially arranged, so that all instructions for an ALD process phase are executed concurrently with that process phase.

Other computer software and/or programs stored on mass storage device 1054 and/or memory device 1056 associated with system controller 1050 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 1018 and to control the spacing between the substrate and other parts of process tool 1000.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 1050. The user interface may include a display screen, graphical software displays of the apparatus and/or process conditions, and user input devices such as pointing devices, keyboards, touch screens, microphones, etc.

In some embodiments, parameters adjusted by system controller 1050 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 1050 from various process tool sensors. The signals for controlling the process may be output on the analog and digital output connections of process tool 1000. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Two or more of the stations may perform the same functions. Similarly, two or more stations may perform different functions. Each station can be designed/configured to perform a particular function/method as desired.

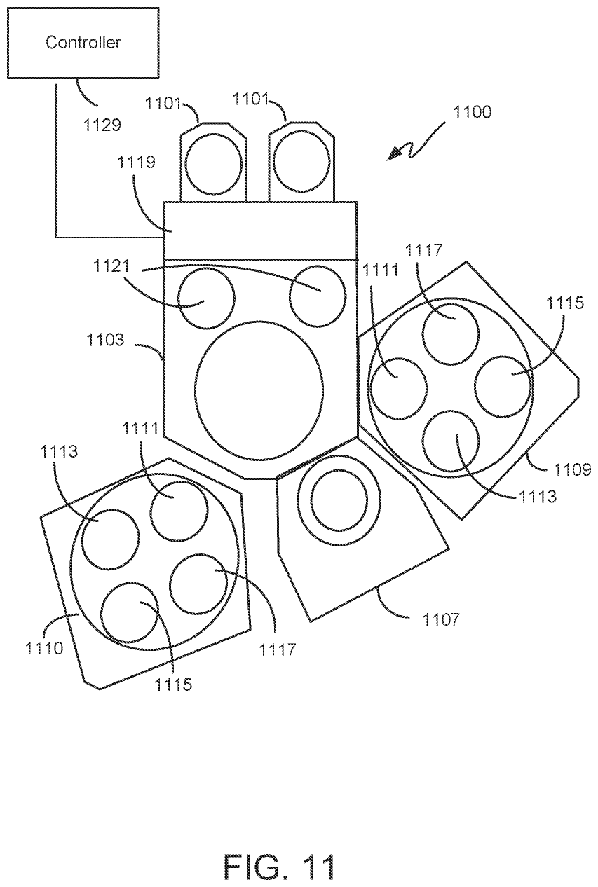

FIG. 11 is a block diagram of a processing system suitable for conducting thin film deposition processes in accordance with certain embodiments. The system 1100 includes a transfer module 1103. The transfer module 1103 provides a clean, pressurized environment to minimize risk of contamination of substrates being processed as they are moved between various reactor modules. Mounted on the transfer module 1103 are two multi-station reactors 1109 and 1110, each capable of performing atomic layer deposition (ALD) and/or chemical vapor deposition (CVD) according to certain embodiments. Reactors 1109 and 1110 may include multiple stations 1111, 1113, 1115, and 1117 that may sequentially or non-sequentially perform operations in accordance with disclosed embodiments. The stations may include a heated pedestal or substrate support, one or more gas inlets or showerhead or dispersion plate.

Also mounted on the transfer module 1103 may be one or more single or multi-station modules 1107 capable of performing plasma or chemical (non-plasma) pre -cleans, or any other processes described in relation to the disclosed methods. The module 1107 may in some cases be used for various treatments to, for example, prepare a substrate for a deposition process. The module 1107 may also be designed/configured to perform various other processes such as etching or polishing. The system 1100 also includes one or more wafer source modules 1101, where wafers are stored before and after processing. An atmospheric robot (not shown) in the atmospheric transfer chamber 1119 may first remove wafers from the source modules 1101 to loadlocks 1121. A wafer transfer device (generally a robot arm unit) in the transfer module 1103 moves the wafers from loadlocks 1121 to and among the modules mounted on the transfer module 1103.

In various embodiments, a system controller 1129 is employed to control process conditions during deposition. The controller 1129 will typically include one or more memory devices and one or more processors. A processor may include a CPU or computer, analog and/or digital input/output connections, stepper motor controller boards, etc.

The controller 1129 may control all of the activities of the deposition apparatus. The system controller 1129 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 1129 may be employed in some embodiments.

Typically, a user interface will be associated with the controller 1129. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface. Signals for monitoring the process may be provided by analog and/or digital input connections of the system controller 1129. The signals for controlling the process are output on the analog and digital output connections of the deposition apparatus 1100.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 1129 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 1129, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer.

In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Further Implementations

The apparatus and processes described herein may be used in conjunction with lithographic patterning tools or processes, for example, for the fabrication or manufacture of semiconductor devices, displays, LEDs, photovoltaic panels, and the like. Typically, though not necessarily, such apparatus and processes will be used or conducted together in a common fabrication facility. Lithographic patterning of a film typically comprises some or all of the following steps, each step enabled with a number of possible tools: (1) application of photoresist on a work piece, i.e., a substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of depositing a film on a semiconductor substrate, the method comprising:
providing a semiconductor substrate in a process chamber;
forming an iodine bond-containing metal species in the process chamber; and
exposing the iodine bond-containing metal species to a reducing agent, thereby forming a metal-containing film on the semiconductor substrate, wherein the reducing agent comprises a hydrogen-containing gas source.

2. The method of claim 1,
wherein forming the iodine bond-containing metal species comprises (i) introducing a metal-containing precursor in the process chamber comprising the semiconductor substrate; and (ii) introducing an iodine-containing reagent to react with the metal-containing precursor, or
wherein forming the iodine bond-containing metal species comprises (i) introducing an iodine-containing reagent to the process chamber comprising the semiconductor substrate; and (ii) introducing a metal-containing precursor to react with the iodine-containing reagent.

3. The method of claim 2, wherein the metal-containing precursor comprises a molybdenum-containing precursor, and wherein the iodine-containing reagent comprises hydrogen iodide, iodine, alkyl iodide, iodosilane, alkyl iodosilane, metal iodide, or metal bromide.

4. The method of claim 1, wherein the hydrogen-containing gas source comprises hydrogen, deuterium, hydrogen and argon, hydrogen and helium, hydrogen and oxygen, hydrogen and nitrogen, ammonia, singly deuterated ammonia, doubly deuterated ammonia, triply deuterated ammonia, hydrazine, an alcohol, an aldehyde, or a combination thereof.

5. A method of forming a molybdenum-containing layer on a substrate comprising:
providing a substrate in a processing chamber;
introducing a low valent molybdenum precursor and at least one reactant into the processing chamber,
wherein the low valent molybdenum precursor comprises an oxidation state of zero, one, two or three,
wherein the low valent molybdenum precursor comprises a structure of Formula (I), Formula (II), or Formula (III): 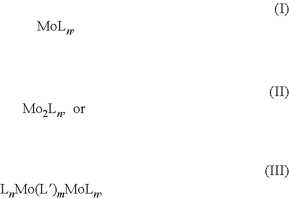
and
wherein:
each L is independently a monodentate ligand, an ambidentate ligand, a bidentate ligand, or a tridentate ligand,
L′ is a linking moiety,
n is 2, 3, 4, 5 or 6; and
m is 1, 2 or 3; and
reacting the low valent molybdenum precursor and the at least one reactant to form a molybdenum-containing layer on the substrate.

6. The method of claim 5,
wherein the low valent molybdenum precursor comprises a structure of formula MoL₄,
wherein the low valent molybdenum precursor comprises a structure of Formula (V): 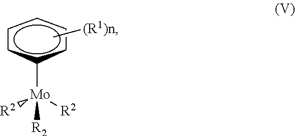
and
wherein:
each R¹ independently comprises an alkyl or a haloalkyl group;
each R² independently comprises a carbonyl, a cyano, an isocyanoalkyl, an isocyanohaloalkyl, an isocyanoaryl, an isocyanohaloaryl, an isocyanato, or an isothiocyanato group; and
n is 0, 1, 2 or 3.

7. The method of claim 5,
wherein the low valent molybdenum precursor comprises a structure of formula MoL₄,
wherein the low valent molybdenum precursor comprises a structure of Formula (VI): 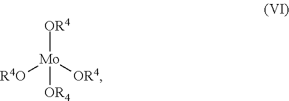
and
wherein each R⁴ is independently an aliphatic, an alkylsilyl, or a haloalkyl group;
or R⁴ substituents may be linked to form a ring.

8. The method of claim 5,
wherein the low valent molybdenum precursor comprises a structure of formula MoL₅
wherein the low valent molybdenum precursor comprises a structure of Formula (X) or Formula (XI): 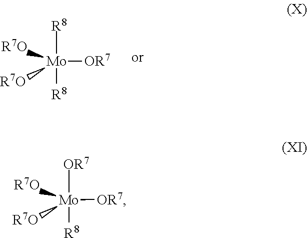
and
wherein:
each R⁷ independently comprises-CH₃, —C₂H₅, —C₃H₇, —C₄H₉, —C₅H₁₁, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃, —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, —P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃ or —SO₂C₆H₄CH₃,
each R⁸ independently comprises allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, imidazolyl, pyrimidinyl, —NO, —CO, —P(CH₃)₃, —P(CH₂CH₃)₃ or —CNR⁹, and
R⁹ comprises an aliphatic, an aryl, or a heterocyclyl group.

9. The method of claim 5,
wherein the low valent molybdenum precursor comprises a structure of formula MoL₃,
wherein the low valent molybdenum precursor comprises a structure of Formula (XIV): 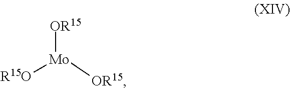
and
wherein each R¹⁵ independently comprises an aliphatic, an alkylsilyl, or a haloalkyl group;
or R¹⁵ substituents may be linked to form a ring.

10. A metal coordination complex comprising a structure of Formula (VI), Formula (IX), Formula (X), Formula (XI), or Formula (XV): 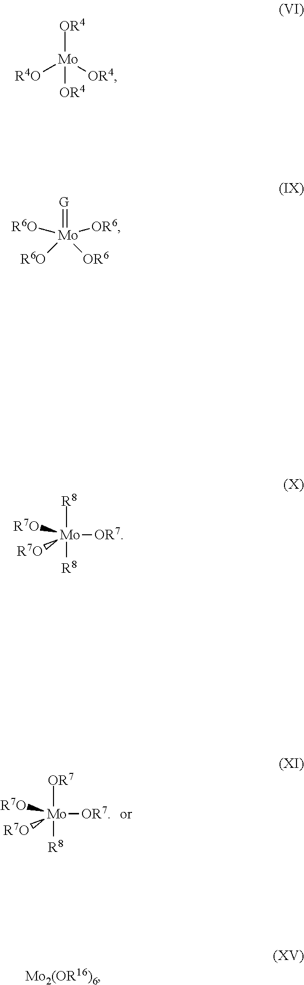
wherein:
R⁴, R⁶, R⁷ and R¹⁶ each independently comprises-CH₃, —C₂H₅, —C₃H₇, —C₄H₉, —C₅H₁₁, —CF₃, —C(F)—CF₂, —C(F)═C(F)CF₃, —CF₂C(F)—CF₂, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃, —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, —P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃ or —SO₂C₆H₄CH₃,
G comprises ═O, ═NR, ═S or ═CR₂,
each R independently comprises an aliphatic, an aryl, a haloalkyl, or haloaryl group,
each R⁸ independently comprises allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, imidazolyl, pyrimidinyl, —NO, —CO, —P(CH₃)₃, —P(CH₂CH₃)₃ or —CNR⁹, and
R⁹ comprises an aliphatic, an aryl, or a heterocyclyl group.

11. A method of depositing a film on a semiconductor substrate, the method comprising:
providing a semiconductor substrate in a process chamber;
forming an iodine bond-containing metal species in the process chamber; and
exposing the iodine bond-containing metal species to a reducing agent, thereby forming a metal-containing film on the semiconductor substrate,
wherein forming the iodine bond-containing metal species comprises (i) introducing a metal-containing precursor in the process chamber comprising the semiconductor substrate; and (ii) introducing an iodine-containing reagent to react with the metal-containing precursor, or wherein forming the iodine bond-containing metal species comprises (i) introducing an iodine-containing reagent to the process chamber comprising the semiconductor substrate; and (ii) introducing a metal-containing precursor to react with the iodine-containing reagent;
wherein the metal-containing precursor comprises a low valent molybdenum precursor, the low valent molybdenum precursor comprises an oxidation state of zero, one, two or three,
wherein the low valent molybdenum precursor comprises a structure of Formula (I), Formula (II), or Formula (III): 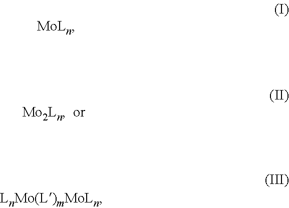
and
wherein:
each L is independently a monodentate ligand, an ambidentate ligand, a bidentate ligand, or a tridentate ligand,
L′ is a linking moiety,
n is 2, 3, 4, 5 or 6; and
m is 1, 2 or 3.
